(19) United States
(12) Patent Application Publication
(10) Pub. No.: US 2003/0102473 A1
(43) Pub. Date: Jun. 5, 2003

(54) Structure and method for fabricating semiconductor structures and devices utilizing the formation of a compliant substrate

(75) Inventors: Marc Chason, Schaumburg, IL (US); George Valliath, Buffalo Grove, IL (US); William J. Ooms, Prescott, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL (US)

(21) Appl. No.: 09/929,024

(22) Filed: Aug. 15, 2001

(51) Int. Cl. H01L 21/00; H01L 29/12; H01L 33/00; H01L 29/76; H01L 29/94; H01L 31/062; H01L 31/113; H01L 31/119

(52) U.S. Cl. 257/43; 438/85; 257/88; 438/22; 257/98; 438/27; 257/103

(57) ABSTRACT

High quality epitaxial layers of monocrystalline materials can be grown overlying a monocrystalline layer of silicon formed on a low cost substrate, such as glass. The growth of the monocrystalline materials is accomplished by forming a compliant substrate for growing the monocrystalline materials. An accommodating buffer layer comprises a layer of monocrystalline oxide spaced apart from a silicon by an amorphous interface layer of silicon oxide. The amorphous interface layer dissipates strain and permits the growth of a high quality monocrystalline oxide accommodating buffer layer. The accommodating buffer layer is lattice matched to both the underlying silicon and the overlying monocrystalline material layer. Any lattice mismatch between the accommodating buffer layer and the underlying silicon layer is taken care of by the amorphous interface layer.

### FIELD OF THE INVENTION

This invention relates generally to semiconductor structures and devices and to a method for their fabrication, and more specifically to semiconductor structures and devices and to the fabrication and use of semiconductor structures, devices, and integrated circuits that include a monocrystalline material layer comprised of semiconductor material, compound semiconductor material, and/or other types of material such as metals and non-metals.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

In addition, attempts have been made to grow crystalline semiconductor films on foreign substrates such as glass or quartz. Substrates such as glass are advantageous in that they are transparent and lower in cost than germanium or silicon wafers. However, attempts to place crystalline semiconductor films on glass substrates have generally been unsuccessful because they result in random polycrystalline structures that are not satisfactory for fabricating some semiconductor devices.

If a large area thin film of high quality monocrystalline material were available on a low cost substrate such as glass, a variety of semiconductor devices could advantageously be fabricated in or using that film at a lower cost compared to the cost of fabricating such devices beginning with a bulk substrate such as silicon. In addition, if a thin film of high quality monocrystalline material could be realized beginning with a substrate such as glass, an integrated device structure could be achieved that took advantage of the best properties of both the glass and the high quality monocrystalline material.

Accordingly, a need exists for a semiconductor structure that provides a high quality monocrystalline film or layer over a low cost substrate such as glass and for a process for making such a structure. This monocrystalline material layer may be comprised of a semiconductor material, a compound semiconductor material, and other types of material such as metals and non-metals.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 is a block diagram of irradiation system that can be used to form the crystalline semiconductor layer on the substrate;

FIGS. 5-10 are top views of a sample structure at sequential stages in a first variant of processing the semiconductor layer on the substrate to form single-crystal regions;

FIGS. 11-16 are top views of a sample structure at sequential stages in a second variant of processing the semiconductor layer on the substrate to form single-crystal regions;

FIGS. 17-19 are top views of a sample structure at sequential stages in a third variant of processing the semiconductor layer on the substrate to form single-crystal regions;

FIG. 20 illustrates graphically the relationship between maximum attainable film thickness and lattice mismatch between a host crystal and a grown crystalline overlayer;

FIG. 21 illustrates a high resolution Transmission Electron Micrograph of a structure including a monocrystalline accommodating buffer layer;

FIG. 22 illustrates an x-ray diffraction spectrum of a structure including a monocrystalline accommodating buffer layer;

FIG. 23 illustrates a high resolution Transmission Electron Micrograph of a structure including an amorphous oxide layer;

FIG. 24 illustrates an x-ray diffraction spectrum of a structure including an amorphous oxide layer;

FIGS. 25-28 illustrate schematically, in cross-section, the formation of a device structure in accordance with another embodiment of the invention;

FIGS. 29-32 illustrate a probable molecular bonding structure of the device structures illustrated in FIGS. 25-28;

FIGS. 33-36 illustrate schematically, in cross-section, the formation of a device structure in accordance with still another embodiment of the invention;

FIGS. 37-39 illustrate schematically, in cross-section, the formation of yet another embodiment of a device structure in accordance with the invention;

FIGS. 40, 41 illustrate schematically, in cross section, device structures that can be used in accordance with various embodiments of the invention;

FIGS. 42-46 are illustrations of cross-sectional views of a portion of an integrated circuit that includes a compound semiconductor portion, a bipolar portion, and an MOS portion in accordance various embodiments of the invention;

FIGS. 47-53 are illustrations of cross-sectional views of a portion of another integrated circuit that includes a semiconductor laser and a MOS transistor in accordance with various embodiments of the invention; and

FIG. 54 illustrates schematically, in cross-section, a portion of a light source device in accordance with an embodiment of the invention.

FIG. 55 is a flow chart that shows a process for fabricating a semiconductor structure in accordance with an embodiment of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

FIG. 1 illustrates schematically, in cross section, a portion of a semiconductor structure 20 in accordance with an embodiment of the invention. Semiconductor structure 20 includes a substrate 21, a thermal oxide layer 23, a monocrystalline semiconductor layer 22, accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of bulk silicon or germanium or mixtures of silicon and germanium and epitaxial layers of such materials commonly found in the semiconductor industry.

In accordance with one embodiment of the invention, structure 20 also includes an amorphous intermediate layer 28 positioned between semiconductor layer 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

The substrate 21 can be any suitable material, e.g., silicon, quartz, glass or plastic, or the like, subject to considerations of stability, inertness and heat resistance under processing conditions. Preferably, the substrate 21 is glass.

In the context of this disclosure, the term “substrate” is normally used to indicate either the substrate 21 or the structure including the substrate 21, the oxide layer 23, and the semiconductor layer 22. The substrate 21 is alternatively called a glass substrate, although it can be formed of other materials, as described herein. The structure including the substrate 21, the oxide layer 23, and the semiconductor layer 22 is alternatively called a monocrystalline substrate, or a silicon substrate (the silicon substrate being one form of the monocrystalline substrate). In some instances in this disclosure, the term monocrystalline substrate refers to a bulk monocrystalline substrate, and the term silicon substrate means a bulk silicon substrate. The term compliant substrate generally refers to the monocrystilline substrate with the accommodating buffer layer 24 formed thereon.

The thermal oxide layer 23 is preferably a layer of silicon dioxide formed or deposited on the surface of the substrate 21.

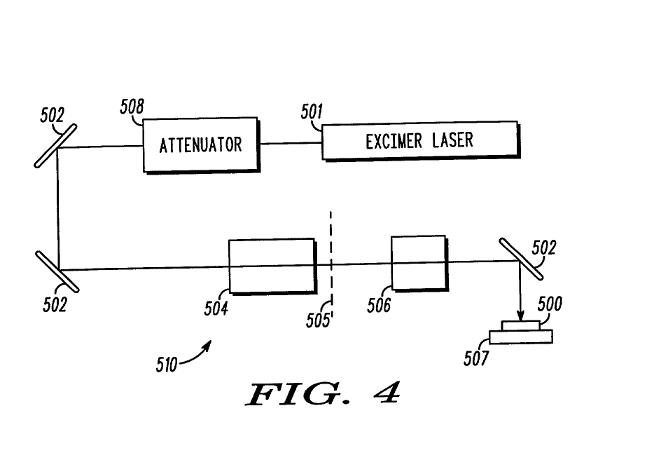

Semiconductor layer 22, in accordance with an embodiment of the invention, is a monocrystalline semiconductor or compound semiconductor film formed on the thermal oxide layer 23 on the substrate 21. The film can be, for example, a material from Group IV of the periodic table. Examples of Group IV semiconductor materials include silicon, germanium, mixed silicon and germanium, mixed silicon and carbon, mixed silicon, germanium and carbon, and the like. Preferably, layer 22 is a film of deposited silicon. The process of forming regions of the monocrystalline semiconductor layer 22 on the substrate 21 is described below in connection with FIGS. 4-19.

Accommodating buffer layer 24 is preferably a monocrystalline oxide or nitride material epitaxially grown on the underlying substrate 21. In accordance with one embodiment of the invention, amorphous intermediate layer 28 is grown on layer 22 at the interface between semiconductor layer 22 and the growing accommodating buffer layer by the oxidation of semiconductor layer 22 during the growth of layer 24. The amorphous intermediate layer serves to relieve strain that might otherwise occur in the monocrystalline accommodating buffer layer as a result of differences in the lattice constants of the semiconductor layer 22 and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying monocrystalline substrate and with the overlying material layer. For example, the material could be an oxide or nitride having a lattice structure closely matched to the semiconductor layer 22 and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

Amorphous interface layer 28 is preferably an oxide formed by the oxidation of the surface of semiconductor layer 22, and more preferably is composed of a silicon oxide. The thickness of layer 28 is sufficient to relieve strain attributed to mismatches between the lattice constants of semiconductor layer 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II(A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. However, monocrystalline material layer 26 may also comprise other semiconductor materials, metals, or non-metal materials which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

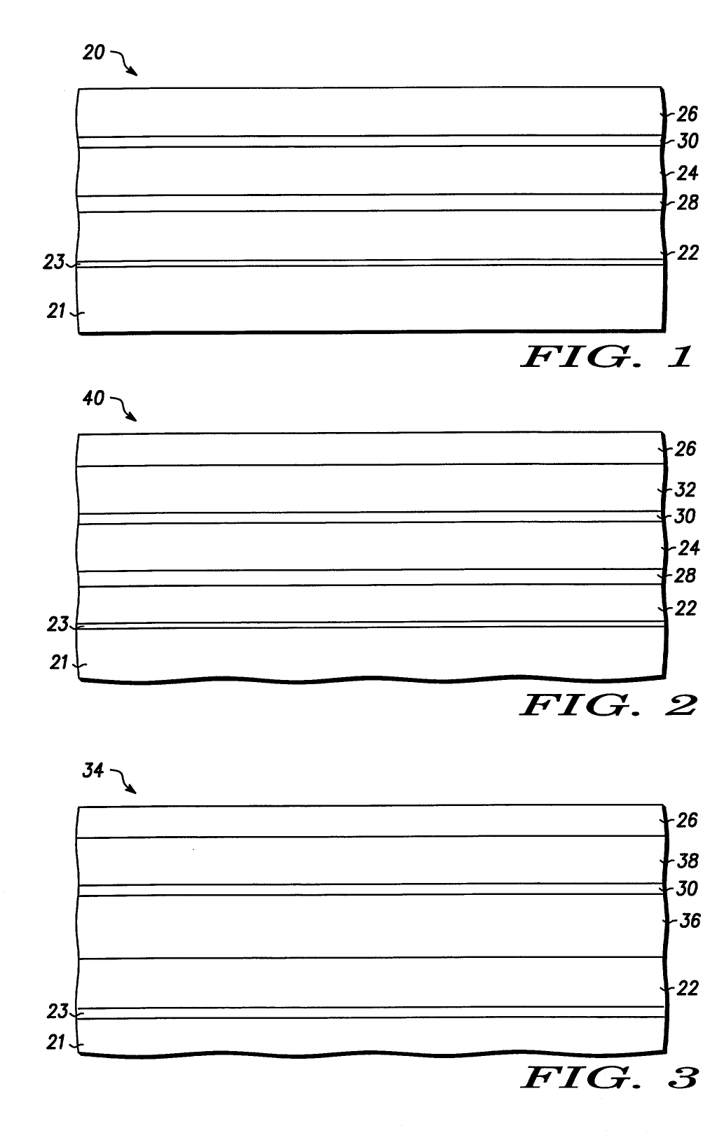

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between semiconductor layer 22 and additional monocrystalline layer 26 (subsequent to layer 38 formation) relieves stresses between layers 22 and 38 and provides a true compliant monocrystalline substrate for subsequent processing—e.g., monocrystalline material layer 26 formation.

The processes previously described above in connection with FIGS. 1 and 2 are adequate for growing monocrystalline material layers over a monocrystalline substrate. However, the process described in connection with FIG. 3, which includes transforming a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

Turning now to FIGS. 4-19, the process by which the monocrystalline semiconductor layer 22 is formed on the substrate 21 is described in further detail.

For forming the monocrystalline semiconductor layer 22 on the substrate 21, a lateral solidification technique is applied to a semiconductor film on the substrate 21. The technique involves irradiating a portion of the film with a suitable radiation pulse, e.g., a laser beam pulse, locally to melt the film completely through its entire thickness. When the molten semiconductor material solidifies, a crystalline structure grows from a pre-selected portion of the film that did not undergo complete melting.

A beam is pulsed repeatedly in forming an extended single-crystal region as a result of laterally stepping a radiation pattern for repeated melting and solidification.

The technique described herein for forming layer 22 over substrate 21 is similar to a technique described in International Patent Application number PCT/US96/07730. Any other technique that results in a monocrystalline semiconductor layer over glass can be used to form the semiconductor layer 22.

FIG. 4 illustrates a block diagram of a projection irradiation system 510 for forming the monocrystalline regions on the glass substrate. The projection irradiation system includes an excimer laser 501, mirrors 502, a variable focus field lens 504, a patterned mask 505, a two-element imaging lens 506, a sample stage 507, and a variable attenuator 508. A sample 500 is disposed on the sample stage 507. This system can be used to produce a shaped beam for stepped growth of a single-crystal silicon region in a sequential lateral solidification (SLS) process. Alternatively, a proximity mask or even a contact mask may be used for beam shaping.

In operation of the system 510, samples are placed onto the stage 507 of the projection irradiation system 510. The mask can have a pattern of simple stripes of 50 micrometers wide, with various separation distances from 10 to 100 micrometers.

In addition radiation beams other than a laser beam can be used, for example, an electron or ion beam.

The sample structure includes the substrate 21, a thermal oxide film 23, and an amorphous silicon film deposited over the thermal oxide film 23.

Structures in accordance with layers 22-23 can prepared by any suitable conventional processing technique, including sequential low-pressure chemical vapor deposition (LPCVD) of SiO₂ and a-Si on a glass or quartz substrate. Other suitable deposition methods, for producing amorphous or microcrystalline deposits, include plasma-enhanced chemical vapor deposition (PECVD), evaporation or sputtering, for example.

The mask pattern is projected onto the samples with different reduction factors in the range from 3 to 6. Samples can be irradiated at room temperature with a 30-nanosecond XeCl excimer laser pulse having a wavelength of 308 nanometers, quartz being transparent at this wavelength. Such a laser is commercially available. For a glass substrate, a longer wavelength can be used, e.g., 348 nanometers.

Irradiation can be with fixed energy density. The energy density can be in the range from 1 to 680 mJ/cm².

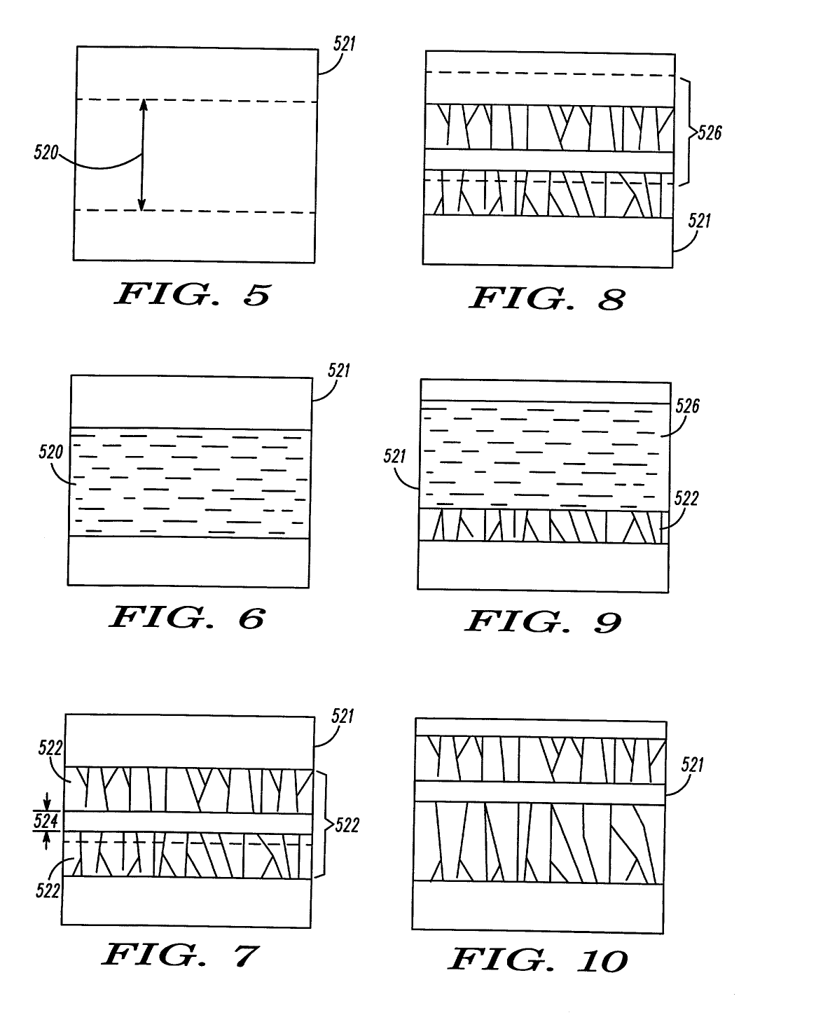

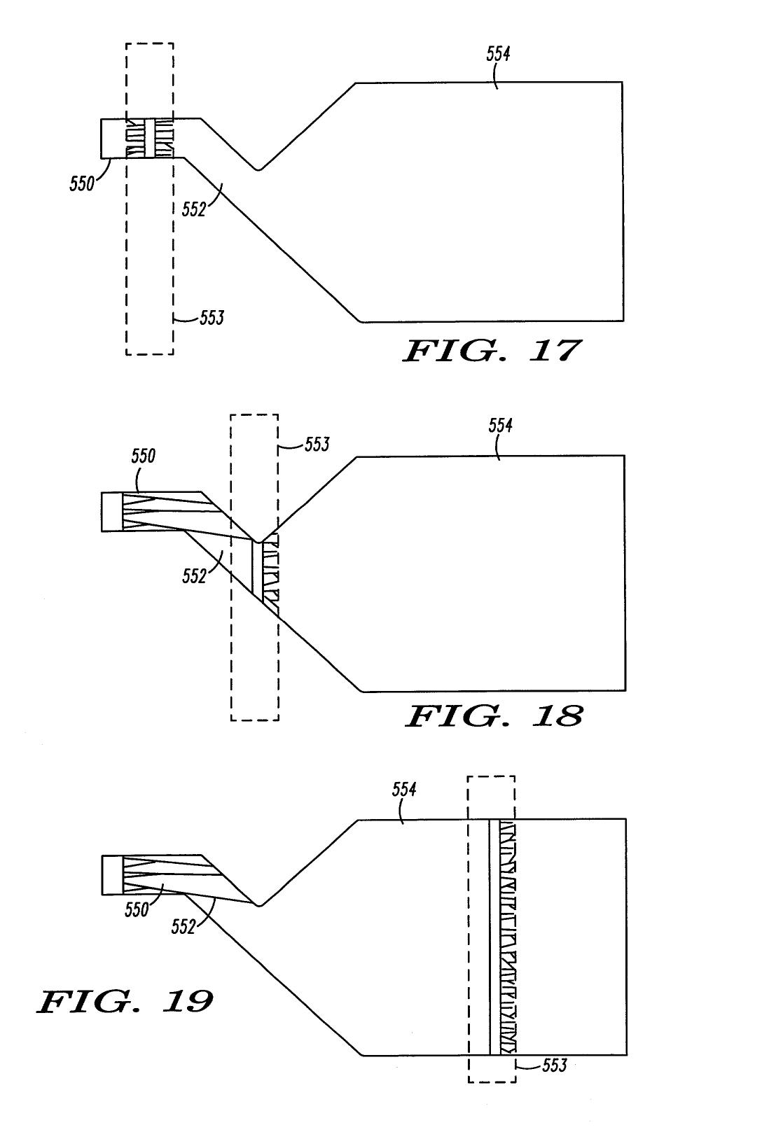

In the following, the sequential lateral solidification (SLS) process is described with reference to FIGS. 5-10 and 11-16 showing first and second variants, respectively, of the process, and FIGS. 17-19 showing a third variant.

Starting with the amorphous silicon film 521, which in this exemplary embodiment is patterned as a rectangle (FIG. 5), a region 520, bounded by two broken lines, of the silicon film 521 is irradiated with a pulse, to completely melt the silicon in that region (FIG. 6), and then resolidify the molten silicon (FIG. 7) in the region 520. Here, the region 520 is in the shape of a stripe, and irradiation of the region 520 may be masked projection or by use of a proximity mask.

Upon re-solidification of the molten silicon in the region 520, two rows 522 of grains grow explosively from the broken line boundaries of the region 520 towards the center of the region 520. In the remainder of region 520, a fine grained polycrystalline region 524 is formed.

Preferably, the width of the stripe is chosen such that, upon resolidification, the two rows of grains approach each other without converging. Smaller widths of the region 520 tend to be undesirable since the subsequent step may have to be reduced in length, and the semiconductor surface may become irregular where grains growing from opposite directions come together during the solidification process. An oxide cap may be formed over the silicon film to retard agglomeration and constrain the surface of the silicon film to be smooth.

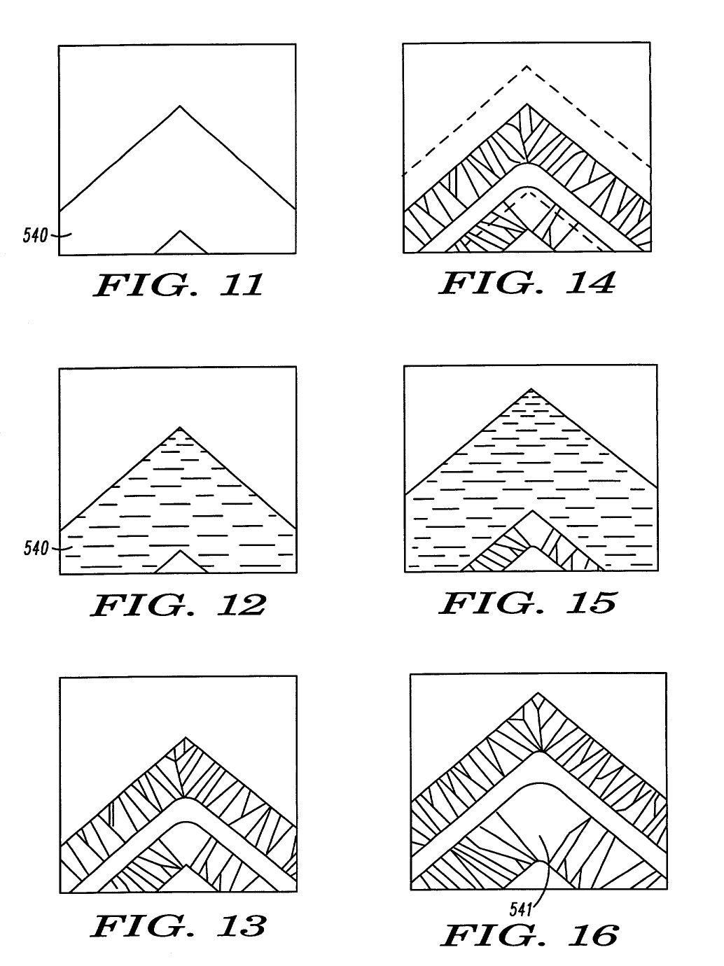

A next region 526 to be irradiated is defined by shifting (stepping) the sample with respect to the masked projection or proximity mask in the direction of crystal growth. The shifted (stepped) region 526 is bounded by two broken lines, as shown in FIG. 8. The distance of the shift is such that the next region 526 to be irradiated overlaps the previously irradiated region 520 so as to completely melt one row of crystals 522 while partially melting the other row of crystals 522, as shown in FIG. 9. Upon resolidification, the partially melted row of crystals becomes longer, as shown in FIG. 10. In this fashion, by repeatedly shifting the irradiated portion, monocrystalline grains of any desired length may be grown.

If the pattern of the irradiated region is not a simple stripe, but is in the shape of a chevron 540, as shown in FIG. 11, the same sequence of shifting the irradiated region shown in FIGS. 12-16 results in the enlargement of one grain growing from the apex of the trailing edge of the shifting (stepping) chevron pattern. In this manner, a monocrystalline region 571 can be grown with increasing width and length.

A large area single-crystal region can also be grown by applying sequentially shifted (stepped) irradiation regions to a patterned amorphous silicon film, such as that illustrated in FIG. 17, having a tail region 550, a narrow bottleneck region 552 and a main island region 554. The region of irradiation 553 defined by masked projection or a proximity mask is illustrated by the regions bounded by broken lines in FIGS. 17-19, which also show the sequential lateral shifting (stepping) of the irradiated region 553 to obtain the growth of a single grain from the tail region 550 through the bottleneck region 552 to produce a single crystal island region 554.

Sequential lateral melting and resolidification in the examples of FIGS. 5-10, 11-16 and 17-19 can be carried out on amorphous silicon films that are deposited by chemical vapor deposition (CVD) on a silicon dioxide coated quartz or glass substrate, with film thicknesses from 100 to 240 nanometers.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline semiconductor layer 22 is a silicon film oriented in the (100) direction. The silicon film can be, for example, a silicon layer as is used in making complementary metal oxide semiconductor (CMOS) integrated circuits. In accordance with this embodiment of the invention, accommodating buffer layer 24 is a monocrystalline layer of Sr_{z}Ba_{1-z}TiO₃ where z ranges from 0 to 1 and the amorphous intermediate layer is a layer of silicon oxide (SiOₓ) formed at the interface between the silicon film and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate the monocrystalline material layer 26 from the silicon layer to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—O. By way of a preferred example, 1-2 monolayers of Ti—As or Sr—Ga—O have been illustrated to successfully grow GaAs layers.

### EXAMPLE 2

In accordance with a further embodiment of the invention, monocrystalline semiconductor layer 22 is a silicon film as described above. The accommodating buffer layer is a monocrystalline oxide of strontium or barium zirconate or hafnate in a cubic or orthorhombic phase with an amorphous intermediate layer of silicon oxide formed at the interface between the silicon layer and the accommodating buffer layer. The accommodating buffer layer can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700 degrees C. The lattice structure of the resulting crystalline oxide exhibits a 45 degree rotation with respect to the silicon film lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is 1-10 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr—As template. A monocrystalline layer of the compound semiconductor material from the indium phosphide system is then grown on the template layer. The resulting lattice structure of the compound semiconductor material exhibits a 45 degree rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon film on the glass substrate. A suitable accommodating buffer layer material is SrₓBa₁₋ₓTiO₃, where x ranges from 0 to 1, having a thickness of about 2-100 nm and preferably a thickness of about 5-15 nm. Where the monocrystalline layer comprises a compound semiconductor material, the II-VI compound semiconductor material can be, for example, zinc selenide (ZnSe) or zinc sulfur selenide (ZnSSe). A suitable template for this material system includes 1-10 monolayers of zinc-oxygen (Zn—O) followed by 1-2 monolayers of an excess of zinc followed by the selenidation of zinc on the surface. Alternatively, a template can be, for example, 1-10 monolayers of strontium-sulfur (Sr—S) followed by the ZnSeS.

### EXAMPLE 4

This embodiment of the invention is an example of structure 40 illustrated in FIG. 2. Semiconductor layer 22, accommodating buffer layer 24, and monocrystalline material layer 26 can be similar to those described in Example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The template for this structure can be the same of that described in Example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline material layer which in this example is a compound semiconductor material. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in a structure 40 as illustrated in FIG. 2. Semiconductor material 22, accommodating buffer layer 24, monocrystalline material layer 26 and template layer 30 can be the same as those described above in Example 2. In addition, additional buffer layer 32 is inserted between the accommodating buffer layer and the overlying monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0 to about 50%. The additional buffer layer 32 preferably has a thickness of about 10-30 nm. Varying the composition of the buffer layer from GaAs to InGaAs serves to provide a lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 3. Semiconductor material 22, template layer 30, and monocrystalline material layer 26 may be the same as those described above in connection with example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z} TiO₃ (where z ranges from 0 to 1), which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 nm to about 100 nm, preferably about 2-10 nm, and more preferably about 5-6 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 monolayer to about 100 nm thick.

Referring again to FIGS. 1-3, semiconductor layer 22 is a monocrystalline region of film, such as a monocrystalline silicon. The crystalline structure of the monocrystalline film is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

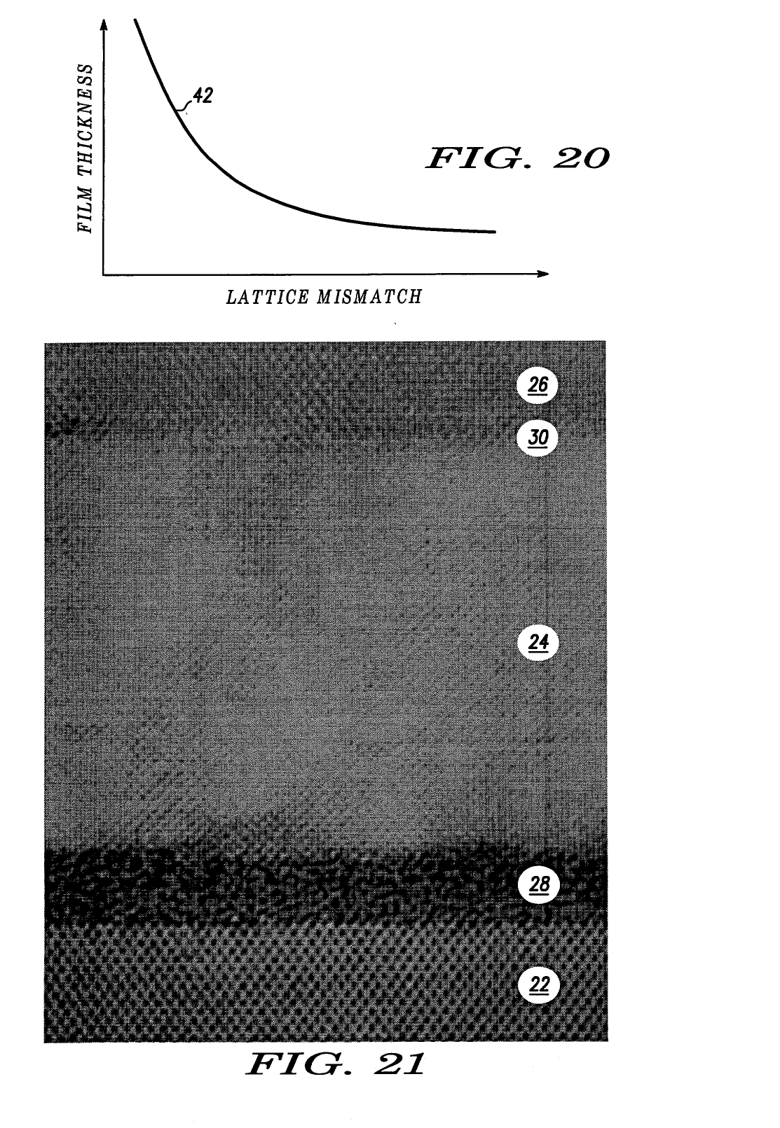

FIG. 20 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, semiconductor layer 22 is a (100) or (111) oriented monocrystalline silicon and accommodating buffer layer 24 is a layer of strontium barium titanate. Substantial matching of lattice constants between these two materials is achieved by rotating the crystal orientation of the titanate material by 45° with respect to the crystal orientation of the silicon. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of semiconductor layer 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a glass substrate having formed thereon regions of single-crystal (monocrystalline) silicon. In accordance with a preferred embodiment of the invention, the monocrystalline silicon regions have a (100) orientation. The silicon regions are preferably oriented on axis or, at most, about 4° off axis. At least a portion of the silicon substrate has a bare surface, although other portions of the silicon substrate, as described below, may encompass other structures. The term “bare” in this context means that the surface in the portions of the silicon substrate has been cleaned to remove any oxides, contaminants, or other foreign material.

In order to epitaxially grow a monocrystalline oxide layer overlying the monocrystalline silicon film, the native oxide layer must first be removed to expose the crystalline structure of the underlying film. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the monocrystalline substrate is then heated to a temperature of about 750° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the film surface can be prepared for the growth of a monocrystalline oxide layer by depositing an alkaline earth metal oxide, such as strontium oxide, strontium barium oxide, or barium oxide, onto the siliconsubstrate surface by MBE at a low temperature and by subsequently heating the structure to a temperature of about 750° C. At this temperature, a solid state reaction takes place between the strontium oxide and the native silicon oxide causing the reduction of the native silicon oxide and leaving an ordered 2×1 structure with strontium, oxygen, and silicon remaining on the silicon substrate surface. Again, this forms a template for the subsequent growth of an ordered monocrystalline oxide layer.

Following the removal of the silicon oxide from the surface of the film, in accordance with one embodiment of the invention, the silicon substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying silicon substrate and the growing strontium titanate layer. The growth of the silicon oxide layer results from the diffusion of oxygen through the growing strontium titanate layer to the interface where the oxygen reacts with silicon at the surface of the underlying silicon substrate. The strontium titanate grows as an ordered (100) monocrystal with the (100) crystalline orientation rotated by 45° with respect to the underlying silicon substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, and arsenic is subsequently introduced with the gallium to form the GaAs.

FIG. 21 is a high resolution Transmission Electron Micrograph (TEM) of semiconductor material manufactured using a bulk silicon substrate. Single crystal SrTiO₃ accommodating buffer layer 24 was grown epitaxially on silicon semiconductor layer 22. During this growth process, amorphous interfacial layer 28 is formed which relieves strain due to lattice mismatch. GaAs compound semiconductor layer 26 was then grown epitaxially using template layer 30. Similar results are predicted for material manufactured using a monocrystalline silicon film formed over a glass layer.

FIG. 22 illustrates an x-ray diffraction spectrum taken on a structure including GaAs monocrystalline layer 26 comprising GaAs grown on a bulk silicon substrate using accommodating buffer layer 24. The peaks in the spectrum indicate that both the accommodating buffer layer 24 and GaAs compound semiconductor layer 26 are single crystal and (100) orientated. Similar results are predicted for material manufactured using a monocrystalline silicon film formed over a glass layer.

The structure illustrated in FIG. 2 can be formed by the process discussed above with the addition of an additional buffer layer deposition step. The additional buffer layer 32 is formed overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 34, illustrated in FIG. 3, may be formed by growing an accommodating buffer layer, forming an amorphous oxide layer over semiconductor layer 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing semiconductor layer 22, the accommodating buffer layer, the amorphous oxide layer, and monocrystalline layer 38 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

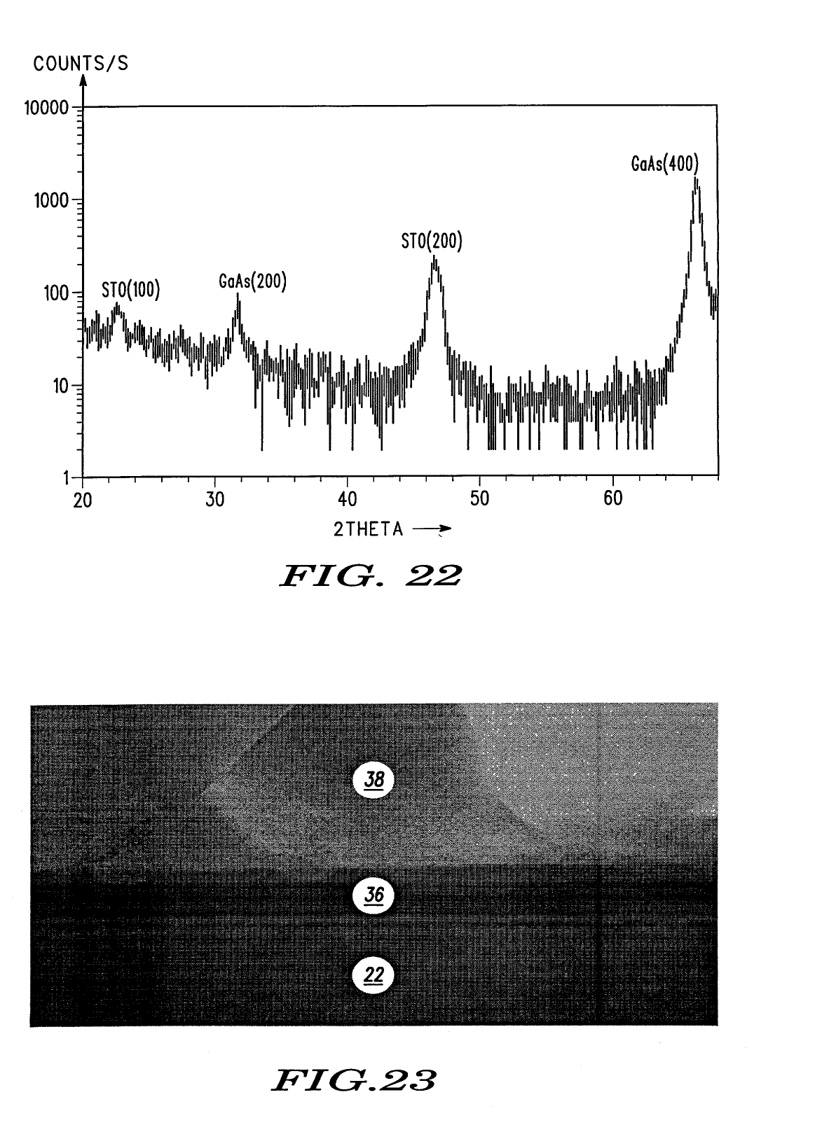

FIG. 23 is a high resolution TEM of semiconductor material manufactured in accordance with the embodiment of the invention illustrated in FIG. 3, but using a bulk silicon substrate. Similar results are predicted for material manufactured using a monocrystalline silicon film formed over a glass layer. In accordance with this embodiment, a single crystal SrTiO₃ accommodating buffer layer was grown epitaxially on a bulk silicon substrate. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

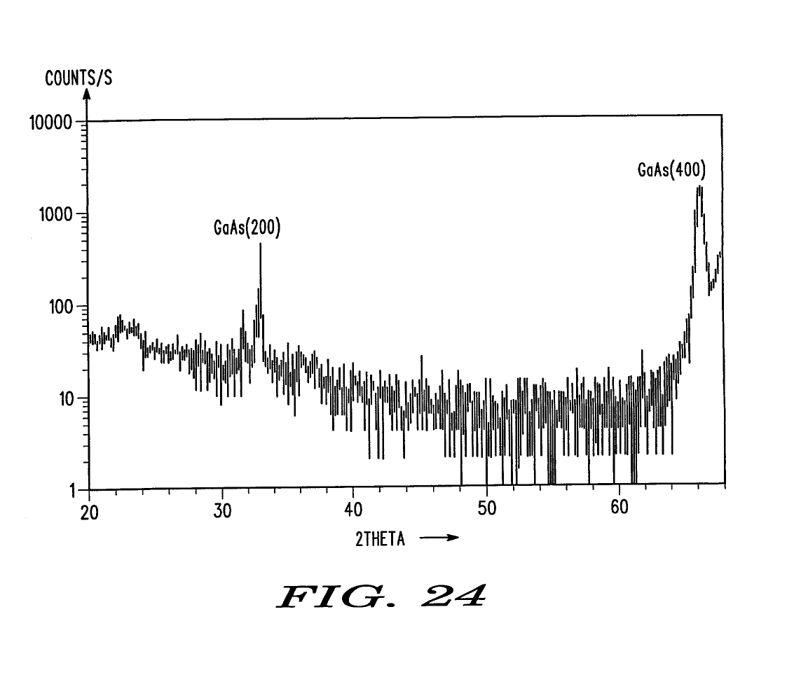

FIG. 24 illustrates an x-ray diffraction spectrum taken on a structure including additional monocrystalline layer 38 comprising a GaAs compound semiconductor layer and amorphous oxide layer 36 formed on a bulk silicon substrate. Similar results are predicted for material manufactured using a monocrystalline silicon film formed over a glass layer. The peaks in the spectrum indicate that GaAs compound semiconductor layer 38 is single crystal and (100) orientated and the lack of peaks around 40 to 50 degrees indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

The formation of a device structure in accordance with another embodiment of the invention is illustrated schematically in cross-section in FIGS. 25-28. Like the previously described embodiments referred to in FIGS. 1-3, this embodiment of the invention involves the process of forming a compliant substrate utilizing the epitaxial growth of single crystal oxides, such as the formation of accommodating buffer layer 24 previously described with reference to FIGS. 1 and 2 and amorphous layer 36 previously described with reference to FIG. 3, and the formation of a template layer 30. However, the embodiment illustrated in FIGS. 25-28 utilizes a template that includes a surfactant to facilitate layer-by-layer monocrystalline material growth.

Turning now to FIG. 25, a glass substrate 51 having a thermal oxide layer 69 and a semiconductor film 52, formed as described above in connection with FIGS. 4-19, is provided. An amorphous intermediate layer 58 is grown on semiconductor film 52 at the interface between the film 52 and a growing accommodating buffer layer 54, which is preferably a monocrystalline crystal oxide layer, by the oxidation of film 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference layer 24 in FIGS. 1-2 and any of those compounds previously described with reference to layer 36 in FIG. 3 which is formed from layers 24 and 28 referenced in FIGS. 1 and 2.

Layer 54 is grown with a strontium (Sr) terminated surface represented in FIG. 25 by hatched line 55 which is followed by the addition of a template layer 60 which includes a surfactant layer 61 and capping layer 63 as illustrated in FIGS. 26 and 27. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of one to two monolayers, over layer 54 as illustrated in FIG. 26 by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a Group V element such as arsenic, for example, to form capping layer 63 as illustrated in FIG. 27. Surfactant layer 61 may be exposed to a number of materials to create capping layer 63 such as elements which include, but are not limited to, As, P, Sb and N. Surfactant layer 61 and capping layer 63 combine to form template layer 60.

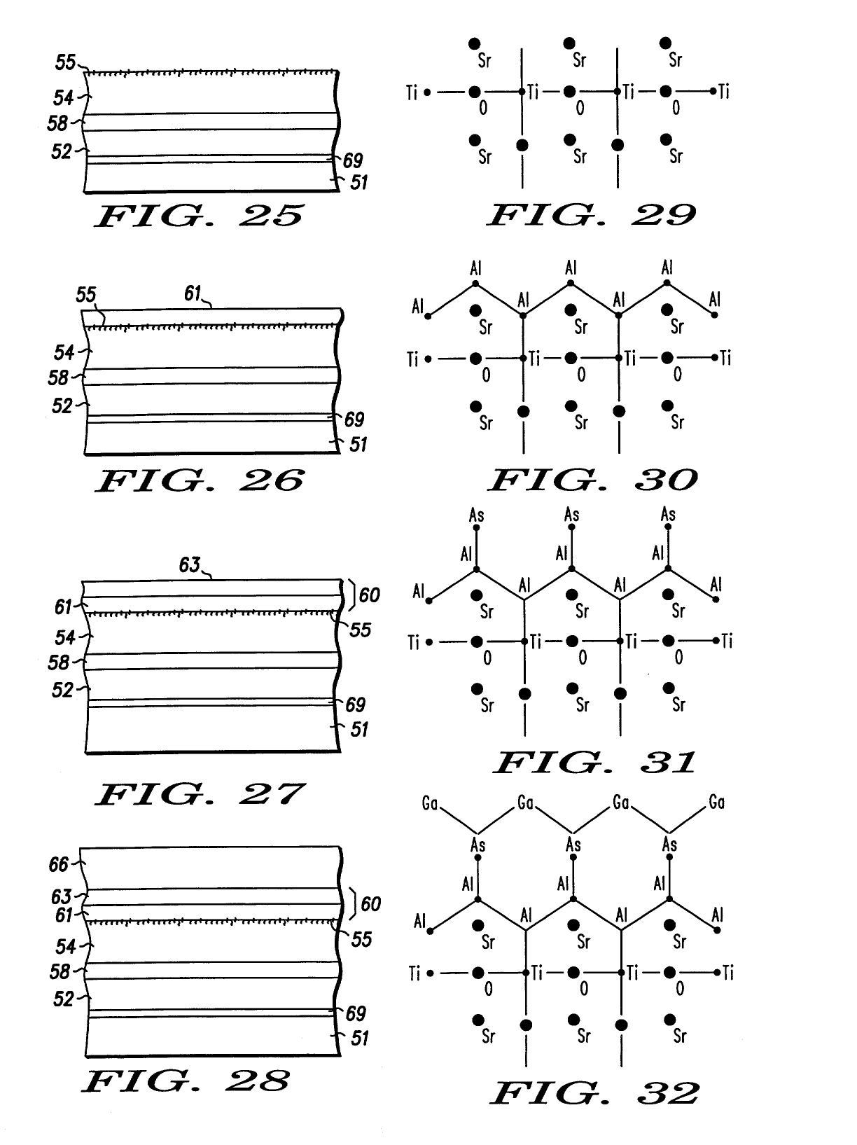

Monocrystalline material layer 66, which in this example is a compound semiconductor such as GaAs, is then deposited via MBE, CVD, MOCVD, MEE, ALE, PVD, CSD, PLD, and the like to form the final structure illustrated in FIG. 28.

FIGS. 29-32 illustrate possible molecular bond structures for a specific example of a compound semiconductor structure formed in accordance with the embodiment of the invention illustrated in FIGS. 25-28. More specifically, FIGS. 29-32 illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and monocrystalline layer 52, both of which may comprise materials previously described with reference to layers 28 and 22, respectively in FIGS. 1 and 2, illustrates a critical thickness of about 1000 Angstroms where the two-dimensional (2D) and three-dimensional (3D) growth shifts because of the surface energies involved. In order to maintain a true layer by layer growth (Frank Van der Mere growth), the following relationship must be satisfied:

δ_{STO}>(δ_{INT}+δ_{GaAs})

where the surface energy of the monocrystalline oxide layer 54 must be greater than the surface energy of the amorphous interface layer 58 added to the surface energy of the GaAs layer 66. Since it is impracticable to satisfy this equation, a surfactant containing template was used, as described above with reference to FIGS. 26-28, to increase the surface energy of the monocrystalline oxide layer 54 and also to shift the crystalline structure of the template to a diamond-like structure that is in compliance with the original GaAs layer.

FIG. 29 illustrates the molecular bond structure of a strontium terminated surface of a strontium titanate monocrystalline oxide layer. An aluminum surfactant layer is deposited on top of the strontium terminated surface and bonds with that surface as illustrated in FIG. 30, which reacts to form a capping layer comprising a monolayer of Al₂Sr having the molecular bond structure illustrated in FIG. 30 which forms a diamond-like structure with an sp³ hybrid terminated surface that is compliant with compound semiconductors such as GaAs. The structure is then exposed to As to form a layer of AlAs as shown in FIG. 31. GaAs is then deposited to complete the molecular bond structure illustrated in FIG. 32 which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 54 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising Germanium (Ge), for example, to form high efficiency photocells.

Turning now to FIGS. 33-36, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

A glass substrate 97 having a layer of thermal oxide deposited 77 thereon, and a region of monocrystalline layer 72 formed thereon as described above in connection with FIGS. 4-19 is provided. An accommodating buffer layer 74 such as a monocrystalline oxide layer is first grown on the monocrystalline layer 72, such as silicon, with an amorphous interface layer 78 as illustrated in FIG. 33. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Layer 72, although preferably silicon, may also comprise any of those materials previously described with reference to semiconductor layer 22 in FIGS. 1-3.

Next, a silicon layer 81 is deposited over monocrystalline oxide layer 74 via MBE, CVD, MOCVD, MEE, ALE, PVD, CSD, PLD, and the like as illustrated in FIG. 34 with a thickness of a few hundred Angstroms but preferably with a thickness of about 50 Angstroms. Monocrystalline oxide layer 74 preferably has a thickness of about 20 to 100 Angstroms.

Rapid thermal annealing is then conducted in the presence of a carbon source such as acetylene or methane, for example at a temperature within a range of about 800° C. to 1000° C. to form capping layer 82 and silicate amorphous layer 86. However, other suitable carbon sources may be used as long as the rapid thermal annealing step functions to amorphize the monocrystalline oxide layer 74 into a silicate amorphous layer 86 and carbonize the top silicon layer 81 to form capping layer 82 which in this example would be a silicon carbide (SiC) layer as illustrated in FIG. 35. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

Finally, a compound semiconductor layer 96, such as gallium nitride (GaN) is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC bulk substrate in the past, this embodiment of the invention possesses a simpler formation of the compliant substrate containing a SiC top surface and an amorphous layer on a Si surface. More specifically, this embodiment of the invention uses an intermediate single crystal oxide layer that is amorphosized to form a silicate layer which adsorbs the strain between the layers. Moreover, unlike past use of a SiC bulk substrate, this embodiment of the invention is not limited by wafer size which is usually less than 50 mm in diameter for prior art SiC bulk substrates.

The monolithic integration of nitride containing semiconductor compounds containing group III-V nitrides and silicon devices can be used for high temperature RF applications and optoelectronics. GaN systems have particular use in the photonic industry for the blue/green and UV light sources and detection. High brightness light emitting diodes (LEDs) and lasers may also be formed within the GaN system.

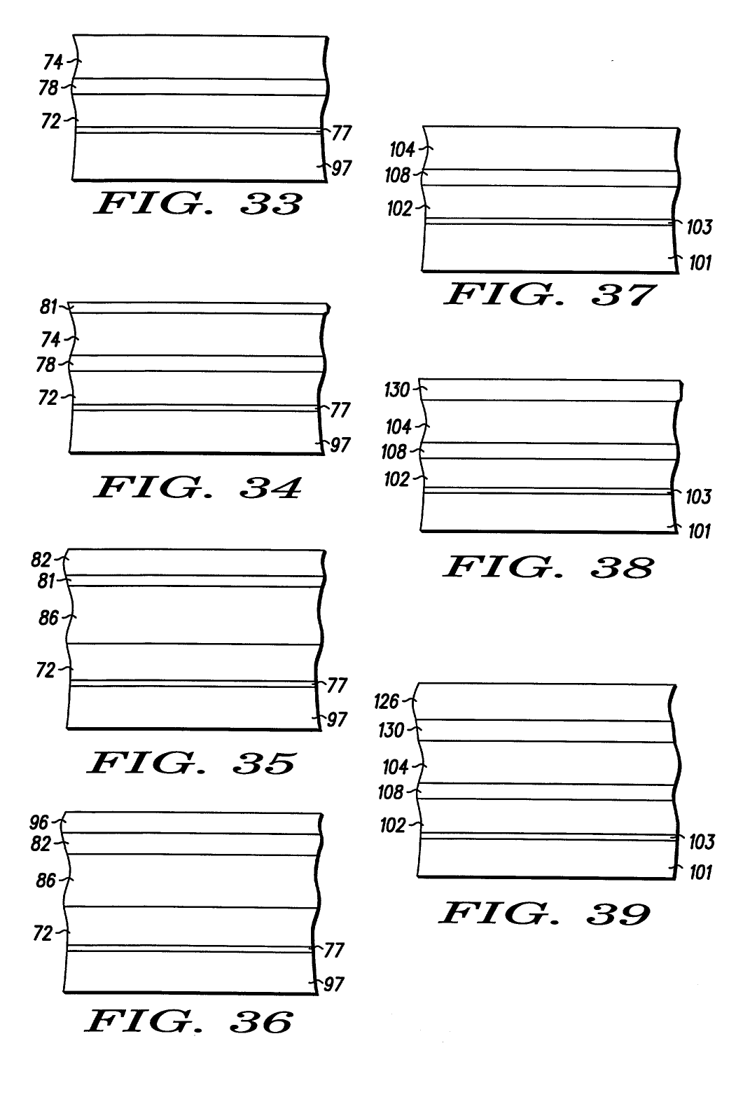

FIGS. 37-39 schematically illustrate, in cross-section, the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers thereby allowing for two dimensional layer by layer growth.

The structure illustrated in FIG. 37 includes substrate 101, such as glass or quartz, a thermal oxide layer 103, a monocrystalline film 102, an amorphous interface layer 108 and an accommodating buffer layer 104. Amorphous interface layer 108 is formed on the monocrystalline film 102 at the interface between monocrystalline film 102 and accommodating buffer layer 104 as previously described with reference to FIGS. 1 and 2. Amorphous interface layer 108 may comprise any of those materials previously described with reference to amorphous interface layer 28 in FIGS. 1 and 2. The monocrystalline film 102 is preferably silicon but may also comprise any of those materials previously described with reference to semiconductor layer 22 in FIGS. 1-3.

A template layer 130 is deposited over accommodating buffer layer 104 as illustrated in FIG. 38 and preferably comprises a thin layer of Zintl type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a “soft” layer with non-directional bonding but high crystallinity which absorbs stress build up between layers having lattice mismatch. Materials for template 130 may include, but are not limited to, materials containing Si, Ga, In, and Sb such as, for example, AlSr₂, (MgCaYb)Ga₂, (Ca,Sr,Eu,Yb)In₂, BaGe₂As, and SrSn₂As₂

A monocrystalline material layer 126 is epitaxially grown over template layer 130 to achieve the final structure illustrated in FIG. 39. As a specific example, an SrAl₂ layer may be used as template layer 130 and an appropriate monocrystalline material layer 126 such as a compound semiconductor material GaAs is grown over the SrAl₂. The Al—Ti (from the accommodating buffer layer of layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zintl phase materials. The amount of the charge transfer depends on the relative electronegativity of elements comprising the template layer 130 as well as on the interatomic distance. In this example, Al assumes an sp³ hybridization and can readily form bonds with monocrystalline material layer 126, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes structures and methods for forming a compliant substrate that is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

A glass or quartz substrate can be used in forming a monocrystalline material layer of a compound semiconductor or a non-compound semiconductor over the glass substrate, thereby forming a “handle” wafer having an essentially transparent nature. This type of wafer overcomes the fragile nature of compound semiconductor or other monocrystalline material wafers by placing semiconductor devices over a relatively more durable base material and allows for uses in which transparency is advantageous. When the wafer comprises monocrystalline silicon over glass, the unique techniques described herein also allow the formation of monocrystalline compound semiconductor materials over the silicon layer, allowing economical combinations of all electrical components, and particularly all active electronic devices, to be formed within or using the monocrystalline material layers even though the substrate itself may include a non-semiconductor material. Fabrication costs for compound semiconductor devices and other devices employing monocrystalline materials should decrease because larger substrates can be processed more economically and more readily compared to the relatively smaller and more fragile substrates (e.g. conventional compound semiconductor wafers).

FIG. 40 illustrates schematically, in cross section, a device structure 50 in accordance with a further embodiment. Device structure 50 includes glass or quartz substrate 51, a thermal oxide layer 69, such as silicon dioxide, a monocrystalline semiconductor layer 52, preferably a monocrystalline silicon region formed as described above in connection with FIGS. 4-19. Monocrystalline semiconductor layer 52 includes two regions, 53 and 57. An electrical semiconductor component generally indicated by the dashed line 56 is formed, at least partially, in region 53. Electrical component 56 can be a resistor, a capacitor, an active semiconductor component such as a diode or a transistor or an integrated circuit such as a CMOS integrated circuit. For example, electrical semiconductor component 56 can be a CMOS integrated circuit configured to perform digital signal processing or another function for which silicon integrated circuits are well suited. The electrical semiconductor component in region 53 can be formed by conventional semiconductor processing as well known and widely practiced in the semiconductor industry. A layer of insulating material 59 such as a layer of silicon dioxide or the like may overlie electrical semiconductor component 56.

Insulating material 59 and any other layers that may have been formed or deposited during the processing of semiconductor component 56 in region 53 are removed from the surface of region 57 to provide a bare silicon surface in that region. As is well known, bare silicon surfaces are highly reactive and a native silicon oxide layer can quickly form on the bare surface. A layer of barium or barium and oxygen is deposited onto the native oxide layer on the surface of region 57 and is reacted with the oxidized surface to form a first template layer (not shown). In accordance with one embodiment, a monocrystalline oxide layer is formed overlying the template layer by a process of molecular beam epitaxy. Reactants including barium, titanium and oxygen are deposited onto the template layer to form the monocrystalline oxide layer. Initially during the deposition the partial pressure of oxygen is kept near the minimum necessary to fully react with the barium and titanium to form monocrystalline barium titanate layer. The partial pressure of oxygen is then increased to provide an overpressure of oxygen and to allow oxygen to diffuse through the growing monocrystalline oxide layer. The oxygen diffusing through the barium titanate reacts with silicon at the surface of region 57 to form an amorphous layer of silicon oxide 62 on second region 57 and at the interface between silicon layer 52 and the monocrystalline oxide layer 65. Layers 65 and 62 may be subject to an annealing process as described above in connection with FIG. 3 to form a single amorphous accommodating layer.

In accordance with an embodiment, the step of depositing the monocrystalline oxide layer 65 is terminated by depositing a second template layer 64, which can be 1-10 monolayers of titanium, barium, barium and oxygen, or titanium and oxygen. A layer 66 of a monocrystalline compound semiconductor material is then deposited overlying second template layer 64 by a process of molecular beam epitaxy. The deposition of layer 66 is initiated by depositing a layer of arsenic onto template 64. This initial step is followed by depositing gallium and arsenic to form monocrystalline gallium arsenide 66. Alternatively, strontium can be substituted for barium in the above example.

In accordance with a further embodiment, a semiconductor component, generally indicated by a dashed line 68 is formed in compound semiconductor layer 66. Semiconductor component 68 can be formed by processing steps conventionally used in the fabrication of gallium arsenide or other III-V compound semiconductor material devices. Semiconductor component 68 can be any active or passive component, and preferably is a semiconductor laser, light emitting diode, photodetector, heterojunction bipolar transistor (HBT), high frequency MESFET, or other component that utilizes and takes advantage of the physical properties of compound semiconductor materials. A metallic conductor schematically indicated by the line 70 can be formed to electrically couple device 68 and device 56, thus implementing an integrated device that includes at least one component formed in silicon layer 52 and one device formed in monocrystalline compound semiconductor material layer 66. Although illustrative structure 50 has been described as a structure formed on a silicon layer 52 and having a barium (or strontium) titanate layer 65 and a gallium arsenide layer 66, similar devices can be fabricated using other substrates, monocrystalline oxide layers and other compound semiconductor layers as described elsewhere in this disclosure.

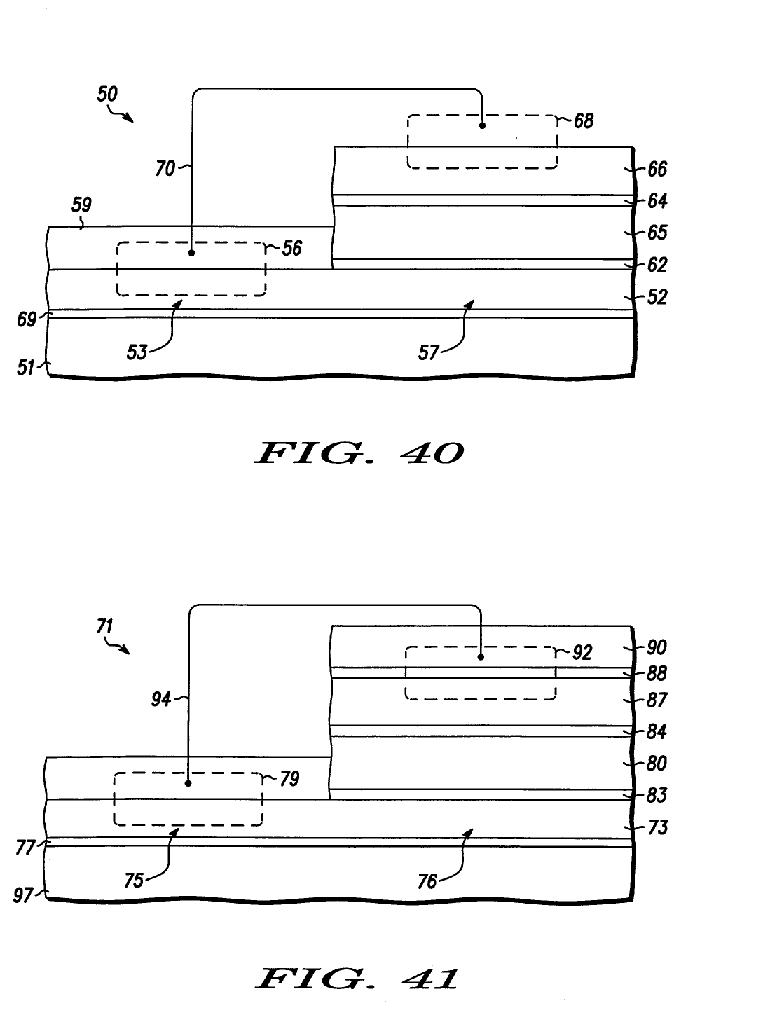

FIG. 41 illustrates a semiconductor structure 71 in accordance with a further embodiment. Structure 71 includes glass or quartz substrate 97, a thermal oxide layer 77, a monocrystalline semiconductor layer 73 such as a monocrystalline silicon film formed on the substrate 97 as described above in connection with FIGS. 4-19 that includes a region 75 and a region 76.

An electrical component schematically illustrated by the dashed line 79 is formed in region 75 using conventional silicon device processing techniques commonly used in the semiconductor industry. Using process steps similar to those described above, a monocrystalline oxide layer 80 and an intermediate amorphous silicon oxide layer 83 are formed overlying region 76 of layer 73. A template layer 84 and subsequently a monocrystalline semiconductor layer 87 are formed overlying monocrystalline oxide layer 80. In accordance with a further embodiment, an additional monocrystalline oxide layer 88 is formed overlying layer 87 by process steps similar to those used to form layer 80, and an additional monocrystalline semiconductor layer 90 is formed overlying monocrystalline oxide layer 88 by process steps similar to those used to form layer 87. In accordance with one embodiment, at least one of layers 87 and 90 are formed from a compound semiconductor material. Layers 80 and 83 may be subject to an annealing process as described above in connection with FIG. 3 to form a single amorphous accommodating layer.

A semiconductor component generally indicated by a dashed line 92 is formed at least partially in monocrystalline semiconductor layer 87. In accordance with one embodiment, semiconductor component 92 may include a field effect transistor having a gate dielectric formed, in part, by monocrystalline oxide layer 88. In addition, monocrystalline semiconductor layer 90 can be used to implement the gate electrode of that field effect transistor. In accordance with one embodiment, monocrystalline semiconductor layer 86 is formed from a group III-V compound and semiconductor component 92 is a radio frequency amplifier that takes advantage of the high mobility characteristic of group III-V component materials. In accordance with yet a further embodiment, an electrical interconnection schematically illustrated by the line 94 electrically interconnects component 79 and component 92. Structure 71 thus integrates components that take advantage of the unique properties of the two monocrystalline semiconductor materials.

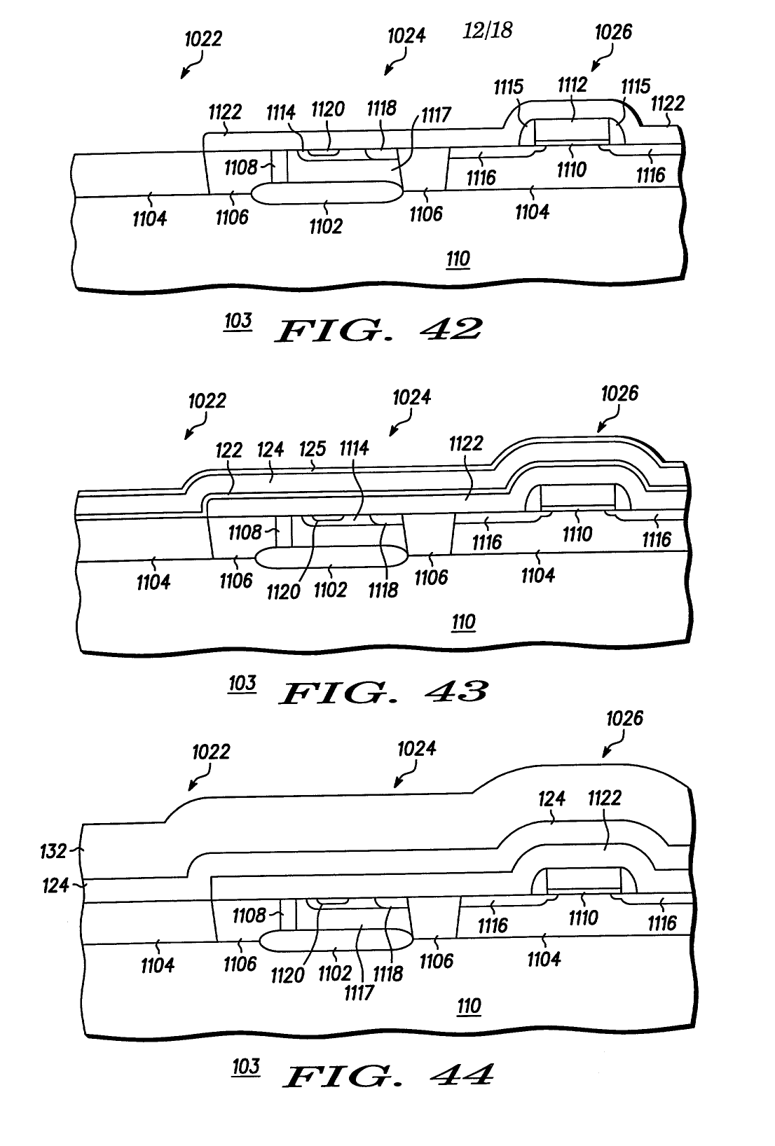

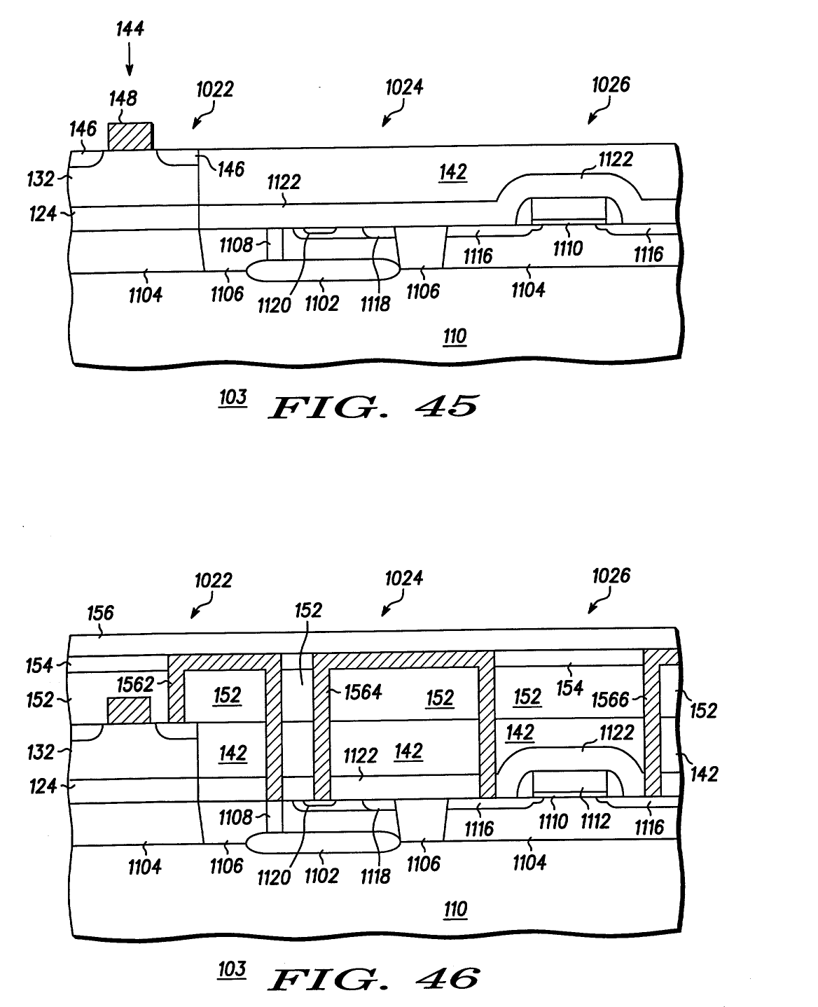

Attention is now directed to a method for forming exemplary portions of illustrative composite semiconductor structures or composite integrated circuits like 50 or 71. In particular, the illustrative composite semiconductor structure or integrated circuit 103 shown in FIGS. 42-46 includes a compound semiconductor portion 1022, a bipolar portion 1024, and a MOS portion 1026. In FIG. 42, a p-type doped, monocrystalline silicon layer 110 is provided over a thermal oxide layer 109 and a glass or quartz substrate 107, formed according to the process described above in connection with FIGS. 4-19. The layer 110 has a compound semiconductor portion 1022, a bipolar portion 1024, and an MOS portion 1026. Within bipolar portion 1024, the monocrystalline silicon layer 110 is doped to form an N+buried region 1102. A lightly p-type doped epitaxial monocrystalline silicon layer 1104 is then formed over the buried region 1102 and the silicon layer 110. A doping step is then performed to create a lightly n-type doped drift region 1117 above the N⁺ buried region 1102. The doping step converts the dopant type of the lightly p-type epitaxial layer within a section of the bipolar region 1024 to a lightly n-type monocrystalline silicon region. A field isolation region 1106 is then formed between and around the bipolar portion 1024 and the MOS portion 1026. A gate dielectric layer 1110 is formed over a portion of the epitaxial layer 1104 within MOS portion 1026, and the gate electrode 1112 is then formed over the gate dielectric layer 1110. Sidewall spacers 1115 are formed along vertical sides of the gate electrode 1112 and gate dielectric layer 1110.

A p-type dopant is introduced into the drift region 1117 to form an active or intrinsic base region 1114. An n-type, deep collector region 1108 is then formed within the bipolar portion 1024 to allow electrical connection to the buried region 1102. Selective n-type doping is performed to form N⁺ doped regions 1116 and the emitter region 1120. N⁺ doped regions 1116 are formed within layer 1104 along adjacent sides of the gate electrode 1112 and are source, drain, or source/drain regions for the MOS transistor. The N⁺ doped regions 1116 and emitter region 1120 have a doping concentration of at least 1E19 atoms per cubic centimeter to allow ohmic contacts to be formed. A p-type doped region is formed to create the inactive or extrinsic base region 1118 which is a P⁺ doped region (doping concentration of at least 1E19 atoms per cubic centimeter).

In the embodiment described, several processing steps have been performed but are not illustrated or further described, such as the formation of well regions, threshold adjusting implants, channel punch through prevention implants, field punch through prevention implants, as well as a variety of masking layers. The formation of the device up to this point in the process is performed using conventional steps. As illustrated, a standard N-channel MOS transistor has been formed within the MOS region 1026, and a vertical NPN bipolar transistor has been formed within the bipolar portion 1024. Although illustrated with a NPN bipolar transistor and a N-channel MOS transistor, device structures and circuits in accordance with various embodiments may additionally or alternatively include other electronic devices formed using the silicon substrate. As of this point, no circuitry has been formed within the compound semiconductor portion 1022.

After the silicon devices are formed in regions 1024 and 1026, a protective layer 1122 is formed overlying devices in regions 1024 and 1026 to protect devices in regions 1024 and 1026 from potential damage resulting from device formation in region 1022. Layer 1122 may be formed of, for example, an insulating material such as silicon oxide or silicon nitride.

All of the layers that have been formed during the processing of the bipolar and MOS portions of the integrated circuit, except for epitaxial layer 1104 but including protective layer 1122, are now removed from the surface of compound semiconductor portion 1022. A bare silicon surface is thus provided for the subsequent processing of this portion, for example in the manner set forth above.

An accommodating buffer layer 124 is then formed over the silicon layer 110 as illustrated in FIG. 43. The accommodating buffer layer will form as a monocrystalline layer over the properly prepared (i.e., having the appropriate template layer) bare silicon surface in portion 1022. The portion of layer 124 that forms over portions 1024 and 1026, however, may be polycrystalline or amorphous because it is formed over a material that is not monocrystalline, and therefore, does not nucleate monocrystalline growth. The accommodating buffer layer 124 typically is a monocrystalline metal oxide or nitride layer and typically has a thickness in a range of approximately 2-100 nanometers. In one particular embodiment, the accommodating buffer layer is approximately 5-15 nm thick. During the formation of the accommodating buffer layer, an amorphous intermediate layer 122 is formed along the uppermost silicon surfaces of the integrated circuit 103. This amorphous intermediate layer 122 typically includes an oxide of silicon and has a thickness and range of approximately 1-5 nm. In one particular embodiment, the thickness is approximately 2 nm. Following the formation of the accommodating buffer layer 124 and the amorphous intermediate layer 122, a template layer 125 is then formed and has a thickness in a range of approximately one to ten monolayers of a material. In one particular embodiment, the material includes titanium-arsenic, strontium-oxygen-arsenic, or other similar materials as previously described with respect to FIGS. 1-3 and 36-37.

A monocrystalline compound semiconductor layer 132 is then epitaxially grown overlying the monocrystalline portion of accommodating buffer layer 124 as shown in FIG. 44. The portion of layer 132 that is grown over portions of layer 124 that are not monocrystalline may be polycrystalline or amorphous. The compound semiconductor layer can be formed by a number of methods and typically includes a material such as gallium arsenide, aluminum gallium arsenide, indium phosphide, or other compound semiconductor materials as previously mentioned. The thickness of the layer is in a range of approximately 1-5,000 nm, and more preferably 100-2000 nm. Furthermore, additional monocrystalline layers maybe formed above layer 132, as discussed in more detail below in connection with FIGS. 31-32.

In this particular embodiment, each of the elements within the template layer are also present in the accommodating buffer layer 124, the monocrystalline compound semiconductor material 132, or both. Therefore, the delineation between the template layer 125 and its two immediately adjacent layers disappears during processing. Therefore, when a transmission electron microscopy (TEM) photograph is taken, an interface between the accommodating buffer layer 124 and the monocrystalline compound semiconductor layer 132 is seen.

After at least a portion of layer 132 is formed in region 1022, layers 122 and 124 may be subject to an annealing process as described above in connection with FIG. 3 to form a single amorphous accommodating layer. If only a portion of layer 132 is formed prior to the anneal process, the remaining portion may be deposited onto structure 103 prior to further processing.

At this point in time, sections of the compound semiconductor layer 132 and the accommodating buffer layer 124 (or of the amorphous accommodating layer if the annealing process described above has been carried out) are removed from portions overlying the bipolar portion 1024 and the MOS portion 1026 as shown in FIG. 45. After the section of the compound semiconductor layer and the accommodating buffer layer 124 are removed, an insulating layer 142 is formed over protective layer 1122. The insulating layer 142 can include a number of materials such as oxides, nitrides, oxynitrides, low-k dielectrics, or the like. As used herein, low-k is a material having a dielectric constant no higher than approximately 3.5. After the insulating layer 142 has been deposited, it is then polished or etched to remove portions of the insulating layer 142 that overlie monocrystalline compound semiconductor layer 132.

A transistor 144 is then formed within the monocrystalline compound semiconductor portion 1022. A gate electrode 148 is then formed on the monocrystalline compound semiconductor layer 132. Doped regions 146 are then formed within the monocrystalline compound semiconductor layer 132. In this embodiment, the transistor 144 is a metal-semiconductor field-effect transistor (MESFET). If the MESFET is an n-type MESFET, the doped regions 146 and at least a portion of monocrystalline compound semiconductor layer 132 are also n-type doped. If a p-type MESFET were to be formed, then the doped regions 146 and at least a portion of monocrystalline compound semiconductor layer 132 would have just the opposite doping type. The heavier doped (N⁺) regions 146 allow ohmic contacts to be made to the monocrystalline compound semiconductor layer 132. At this point in time, the active devices within the integrated circuit have been formed. Although not illustrated in the drawing figures, additional processing steps such as formation of well regions, threshold adjusting implants, channel punchthrough prevention implants, field punchthrough prevention implants, and the like may be performed in accordance with the present invention. This particular embodiment includes an n-type MESFET, a vertical NPN bipolar transistor, and a planar n-channel MOS transistor. Many other types of transistors, including P-channel MOS transistors, p-type vertical bipolar transistors, p-type MESFETs, and combinations of vertical and planar transistors, can be used. Also, other electrical components, such as resistors, capacitors, diodes, and the like, may be formed in one or more of the portions 1022, 1024, and 1026.

Processing continues to form a substantially completed integrated circuit 103 as illustrated in FIG. 46. An insulating layer 152 is formed over the silicon layer 110. The insulating layer 152 may include an etch-stop or polish-stop region that is not illustrated in FIG. 46. A second insulating layer 154 is then formed over the first insulating layer 152. Portions of layers 154, 152, 142, 124, and 1122 are removed to define contact openings where the devices are to be interconnected. Interconnect trenches are formed within insulating layer 154 to provide the lateral connections between the contacts. As illustrated in FIG. 46, interconnect 1562 connects a source or drain region of the n-type MESFET within portion 1022 to the deep collector region 1108 of the NPN transistor within the bipolar portion 1024. The emitter region 1120 of the NPN transistor is connected to one of the doped regions 1116 of the n-channel MOS transistor within the MOS portion 1026. The other doped region 1116 is electrically connected to other portions of the integrated circuit that are not shown. Similar electrical connections are also formed to couple regions 1118 and 1112 to other regions of the integrated circuit.

A passivation layer 156 is formed over the interconnects 1562, 1564, and 1566 and insulating layer 154. Other electrical connections are made to the transistors as illustrated as well as to other electrical or electronic components within the integrated circuit 103 but are not illustrated in the FIGS. Further, additional insulating layers and interconnects may be formed as necessary to form the proper interconnections between the various components within the integrated circuit 103.

As can be seen from the previous embodiment, active devices for both compound semiconductor and Group IV semiconductor materials can be integrated into a single integrated circuit. Because there is some difficulty in incorporating both bipolar transistors and MOS transistors within a same integrated circuit, it may be possible to move some of the components within bipolar portion 1024 into the compound semiconductor portion 1022 or the MOS portion 1026. Therefore, the requirement of special fabricating steps solely used for making a bipolar transistor can be eliminated. Therefore, there would only be a compound semiconductor portion and a MOS portion to the integrated circuit.

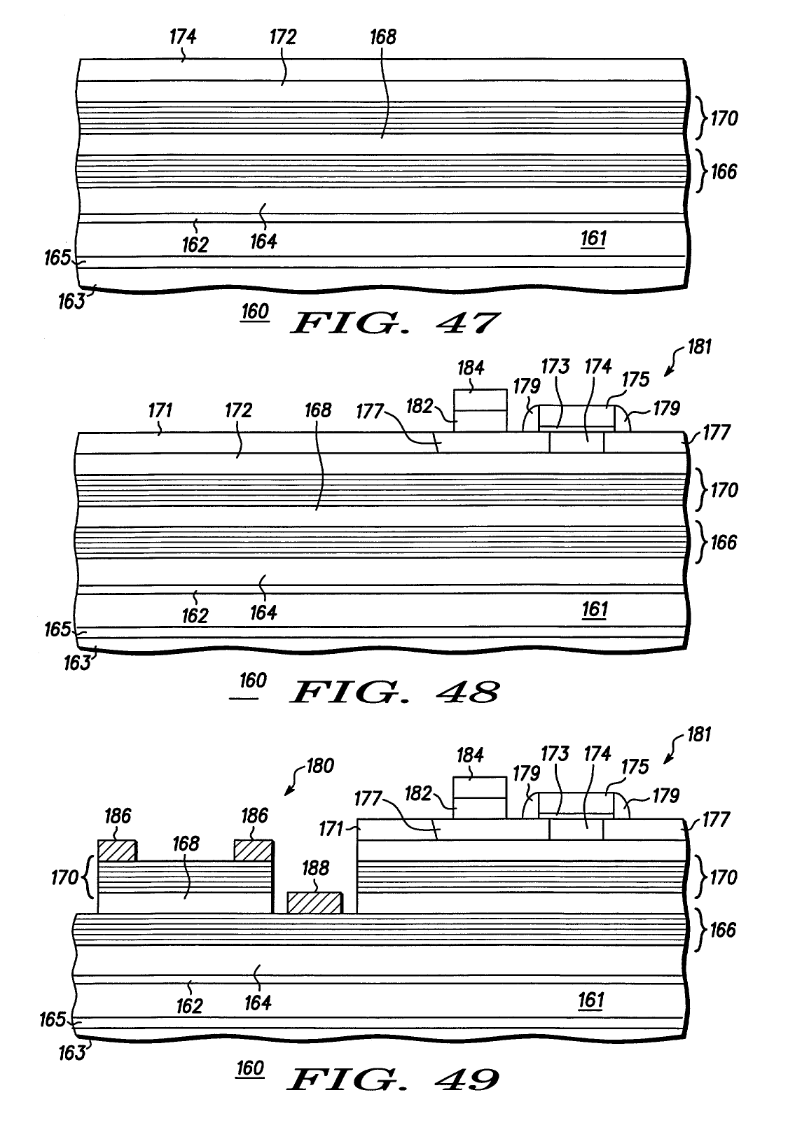

In still another embodiment, an integrated circuit can be formed such that it includes an optical laser in a compound semiconductor portion and an optical interconnect (waveguide) to a MOS transistor within a Group IV semiconductor region of the same integrated circuit. FIGS. 47-53 include illustrations of one embodiment.

FIG. 47 includes an illustration of a cross-section view of a portion of an integrated circuit 160 that includes a glass or quartz substrate 163, a thermal oxide layer 165, and a monocrystalline silicon layer 161 formed on the substrate 163 as described above in connection with FIGS. 4-19. An amorphous intermediate layer 162 and an accommodating buffer layer 164, similar to those previously described, have been formed over layer 161. Layers 162 and 164 may be subject to an annealing process as described above in connection with FIG. 3 to form a single amorphous accommodating layer. In this specific embodiment, the layers needed to form the optical laser will be formed first, followed by the layers needed for the MOS transistor. In FIG. 47, the lower mirror layer 166 includes alternating layers of compound semiconductor materials. For example, the first, third, and fifth films within the optical laser may include a material such as gallium arsenide, and the second, fourth, and sixth films within the lower mirror layer 166 may include aluminum gallium arsenide or vice versa. Layer 168 includes the active region that will be used for photon generation. Upper mirror layer 170 is formed in a similar manner to the lower mirror layer 166 and includes alternating films of compound semiconductor materials. In one particular embodiment, the upper mirror layer 170 may be p-type doped compound semiconductor materials, and the lower mirror layer 166 may be n-type doped compound semiconductor materials.

Another accommodating buffer layer 172, similar to the accommodating buffer layer 164, is formed over the upper mirror layer 170. In an alternative embodiment, the accommodating buffer layers 164 and 172 may include different materials. However, their function is essentially the same in that each is used for making a transition between a compound semiconductor layer and a monocrystalline Group IV semiconductor layer. Layer 172 may be subject to an annealing process as described above in connection with FIG. 3 to form an amorphous accommodating layer. A monocrystalline Group IV semiconductor layer 174 is formed over the accommodating buffer layer 172. In one particular embodiment, the monocrystalline Group IV semiconductor layer 174 includes germanium, silicon germanium, silicon germanium carbide, or the like.

In FIG. 48, the MOS portion is processed to form electrical components within this upper monocrystalline Group IV semiconductor layer 174. As illustrated in FIG. 48, a field isolation region 171 is formed from a portion of layer 174. A gate dielectric layer 173 is formed over the layer 174, and a gate electrode 175 is formed over the gate dielectric layer 173. Doped regions 177 are source, drain, or source/drain regions for the transistor 181, as shown. Sidewall spacers 179 are formed adjacent to the vertical sides of the gate electrode 175. Other components can be made within at least a part of layer 174. These other components include other transistors (n-channel or p-channel), capacitors, transistors, diodes, and the like.

A monocrystalline Group IV semiconductor layer is epitaxially grown over one of the doped regions 177. An upper portion 184 is P+ doped, and a lower portion 182 remains substantially intrinsic (undoped) as illustrated in FIG. 48. The layer can be formed using a selective epitaxial process. In one embodiment, an insulating layer (not shown) is formed over the transistor 181 and the field isolation region 171. The insulating layer is patterned to define an opening that exposes one of the doped regions 177. At least initially, the selective epitaxial layer is formed without dopants. The entire selective epitaxial layer may be intrinsic, or a p-type dopant can be added near the end of the formation of the selective epitaxial layer. If the selective epitaxial layer is intrinsic, as formed, a doping step may be formed by implantation or by furnace doping. Regardless how the P+ upper portion 184 is formed, the insulating layer is then removed to form the resulting structure shown in FIG. 48.

The next set of steps is performed to define the optical laser 180 as illustrated in FIG. 49. The field isolation region 171 and the accommodating buffer layer 172 are removed over the compound semiconductor portion of the integrated circuit. Additional steps are performed to define the upper mirror layer 170 and active layer 168 of the optical laser 180. The sides of the upper mirror layer 170 and active layer 168 are substantially coterminous. Contacts 186 and 188 are formed for making electrical contact to the upper mirror layer 170 and the lower mirror layer 166, respectively, as shown in FIG. 49. Contact 186 has an annular shape to allow light (photons) to pass out of the upper mirror layer 170 into a subsequently formed optical waveguide.

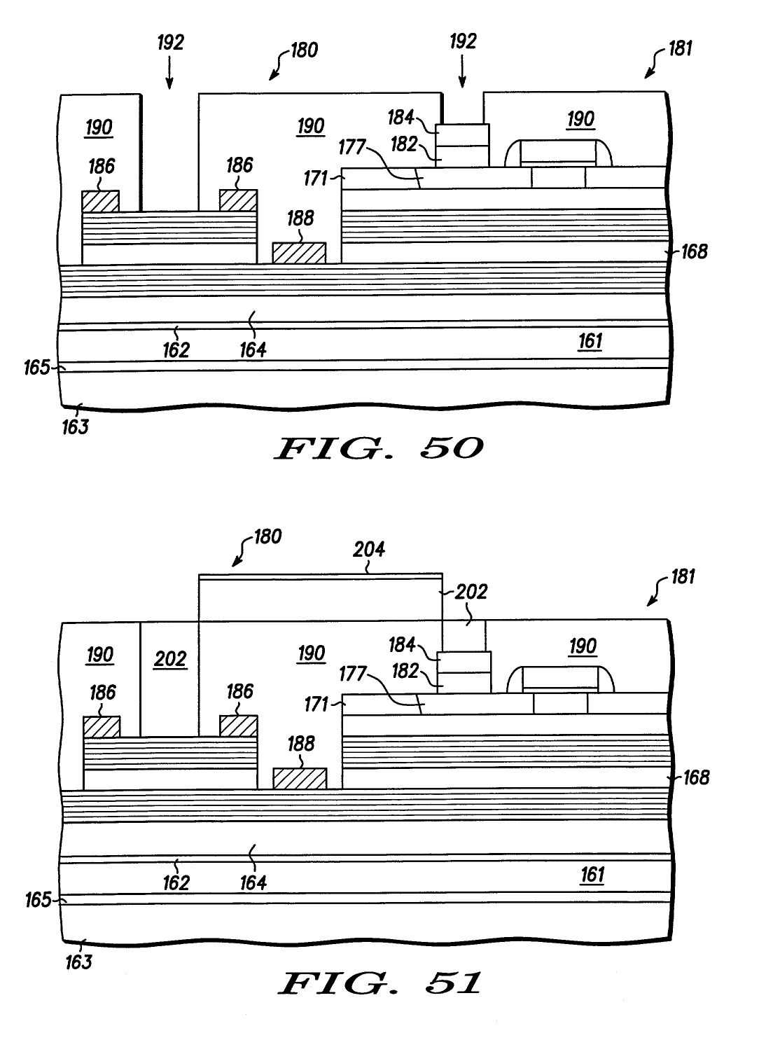

An insulating layer 190 is then formed and patterned to define optical openings extending to the contact layer 186 and one of the doped regions 177 as shown in FIG. 50. The insulating material can be any number of different materials, including an oxide, nitride, oxynitride, low-k dielectric, or any combination thereof. After defining the openings 192, a higher refractive index material 202 is then formed within the openings to fill them and to deposit the layer over the insulating layer 190 as illustrated in FIG. 51. With respect to the higher refractive index material 202, “higher” is in relation to the material of the insulating layer 190 (i.e., material 202 has a higher refractive index compared to the insulating layer 190). Optionally, a relatively thin lower refractive index film (not shown) could be formed before forming the higher refractive index material 202. A hard mask layer 204 is then formed over the high refractive index layer 202. Portions of the hard mask layer 204, and high refractive index layer 202 are removed from portions overlying the opening and to areas closer to the sides of FIG. 51.

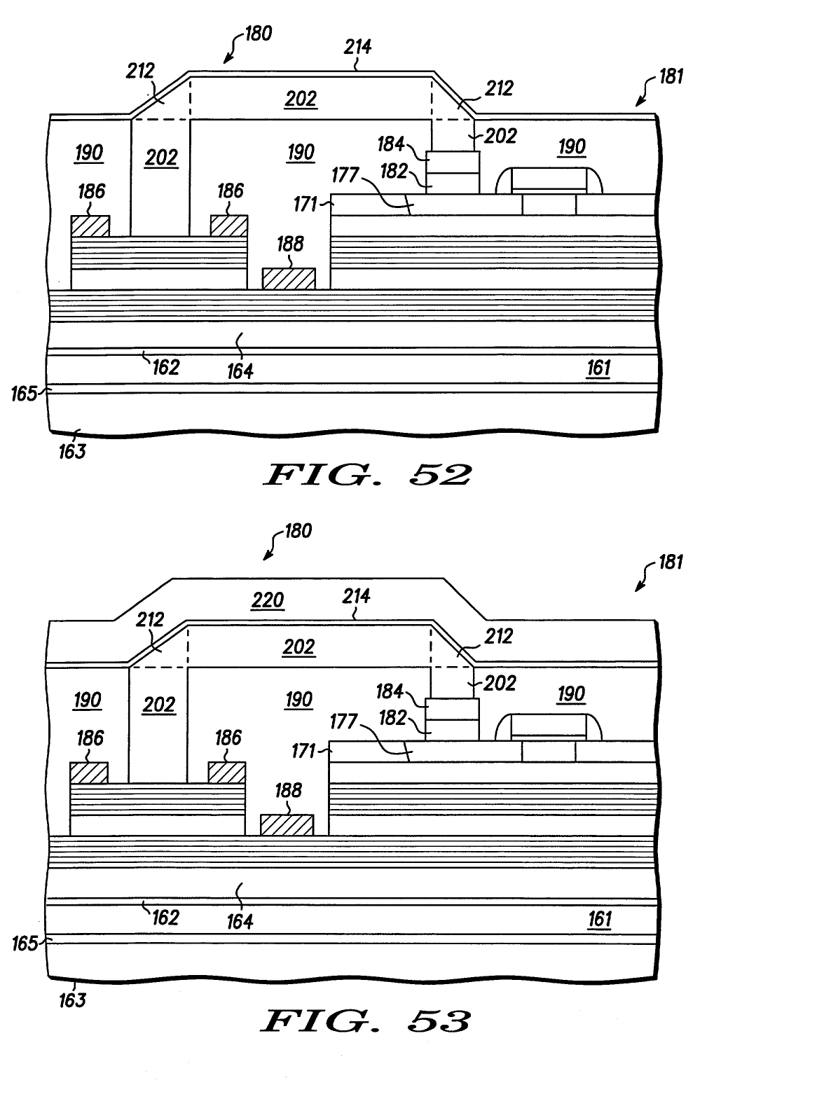

The balance of the formation of the optical waveguide, which is an optical interconnect, is completed as illustrated in FIG. 52. A deposition procedure (possibly a dep-etch process) is performed to effectively create sidewalls sections 212. In this embodiment, the sidewall sections 212 are made of the same material as material 202. The hard mask layer 204 is then removed, and a low refractive index layer 214 (low relative to material 202 and layer 212) is formed over the higher refractive index material 212 and 202 and exposed portions of the insulating layer 190. The dash lines in FIG. 52 illustrate the border between the high refractive index materials 202 and 212. This designation is used to identify that both are made of the same material but are formed at different times.

Processing is continued to form a substantially completed integrated circuit as illustrated in FIG. 53. A passivation layer 220 is then formed over the optical laser 180 and MOSFET transistor 181. Although not shown, other electrical or optical connections are made to the components within the integrated circuit but are not illustrated in FIG. 53. These interconnects can include other optical waveguides or may include metallic interconnects.

In other embodiments, other types of lasers can be formed. For example, another type of laser can emit light (photons) horizontally instead of vertically. If light is emitted horizontally, the MOSFET transistor could be formed within the silicon layer 161, and the optical waveguide would be reconfigured, so that the laser is properly coupled (optically connected) to the transistor. In one specific embodiment, the optical waveguide can include at least a portion of the accommodating buffer layer. Other configurations are possible.

Clearly, these embodiments of integrated circuits having compound semiconductor portions and Group IV semiconductor portions, are meant to illustrate what can be done and are not intended to be exhaustive of all possibilities or to limit what can be done. There is a multiplicity of other possible combinations and embodiments. For example, the compound semiconductor portion may include light emitting diodes, photodetectors, diodes, or the like, and the Group IV semiconductor can include digital logic, memory arrays, and most structures that can be formed in conventional MOS integrated circuits. By using what is shown and described herein, it is now simpler to integrate devices that work better in compound semiconductor materials with other components that work better in Group IV semiconductor materials. This allows a device to be shrunk, the manufacturing costs to decrease, and yield and reliability to increase.

A composite integrated circuit may include components that provide electrical isolation when electrical signals are applied to the composite integrated circuit. The composite integrated circuit may include a pair of optical components, such as an optical source component and an optical detector component. An optical source component may be a light generating semiconductor device, such as an optical laser (e.g., the optical laser illustrated in FIG. 45), a photo emitter, a diode, etc. An optical detector component may be a light-sensitive semiconductor junction device, such as a photodetector, a photodiode, a bipolar junction, a transistor, etc.

A composite integrated circuit may include processing circuitry that is formed at least partly in the Group IV semiconductor portion of the composite integrated circuit. The processing circuitry is configured to communicate with circuitry external to the composite integrated circuit. The processing circuitry may be electronic circuitry, such as a microprocessor, RAM, logic device, decoder, etc.

For the processing circuitry to communicate with external electronic circuitry, the composite integrated circuit may be provided with electrical signal connections with the external electronic circuitry. The composite integrated circuit may have internal optical communications connections for connecting the processing circuitry in the composite integrated circuit to the electrical connections with the external circuitry. Optical components in the composite integrated circuit may provide the optical communications connections which may electrically isolate the electrical signals in the communications connections from the processing circuitry. Together, the electrical and optical communications connections may be for communicating information, such as data, control, timing, etc.

A pair of optical components (an optical source component and an optical detector component) in the composite integrated circuit may be configured to pass information. Information that is received or transmitted between the optical pair may be from or for the electrical communications connection between the external circuitry and the composite integrated circuit. The optical components and the electrical communications connection may form a communications connection between the processing circuitry and the external circuitry while providing electrical isolation for the processing circuitry. If desired, a plurality of optical component pairs may be included in the composite integrated circuit for providing a plurality of communications connections and for providing isolation. For example, a composite integrated circuit receiving a plurality of data bits may include a pair of optical components for communication of each data bit.

In operation, for example, an optical source component in a pair of components may be configured to generate light (e.g., photons) based on receiving electrical signals from an electrical signal connection with the external circuitry. An optical detector component in the pair of components may be optically connected to the source component to generate electrical signals based on detecting light generated by the optical source component. Information that is communicated between the source and detector components may be digital or analog.

If desired the reverse of this configuration may be used. An optical source component that is responsive to the on-board processing circuitry may be coupled to an optical detector component to have the optical source component generate an electrical signal for use in communications with external circuitry. A plurality of such optical component pair structures may be used for providing two-way connections. In some applications where synchronization is desired, a first pair of optical components may be coupled to provide data communications and a second pair may be coupled for communicating synchronization information.

For clarity and brevity, optical detector components that are discussed below are discussed primarily in the context of optical detector components that have been formed in a compound semiconductor portion of a composite integrated circuit. In application, the optical detector component may be formed in many suitable ways (e.g., formed from silicon, etc.).

A composite integrated circuit will typically have an electric connection for a power supply and a ground connection. The power and ground connections are in addition to the communications connections that are discussed above. Processing circuitry in a composite integrated circuit may include electrically isolated communications connections and include electrical connections for power and ground. In most known applications, power supply and ground connections are usually well-protected by circuitry to prevent harmful external signals from reaching the composite integrated circuit. A communications ground may be isolated from the ground signal in communications connections that use a ground communications signal.

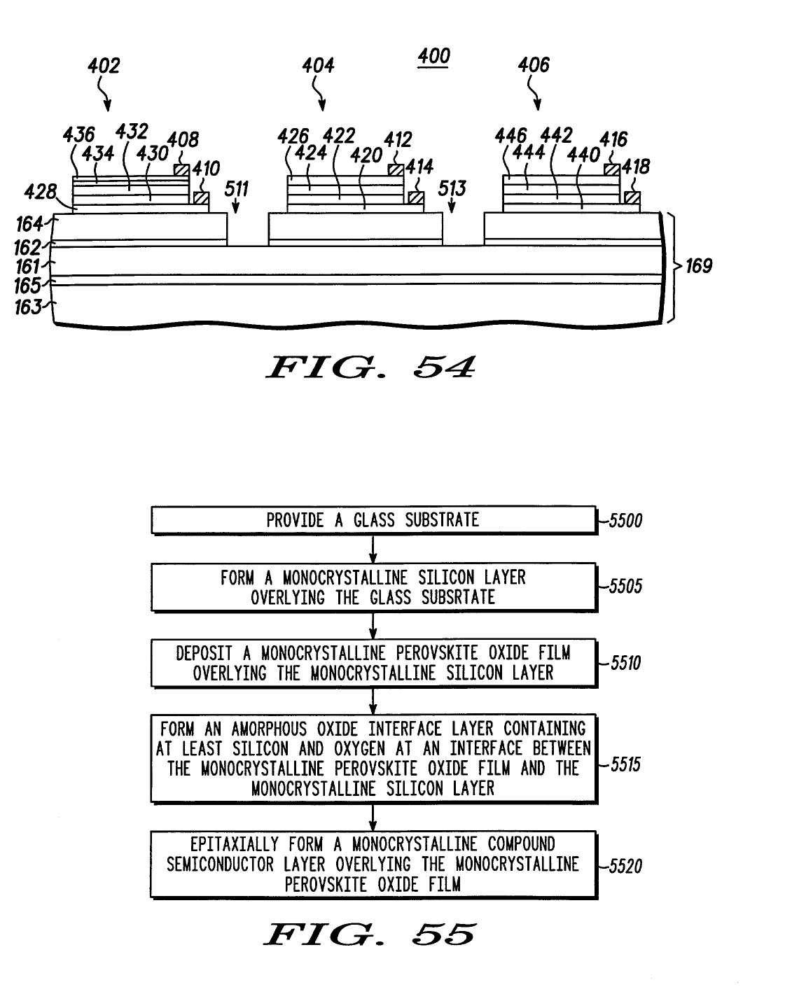

FIG. 54 illustrates schematically, in cross-section, a portion of a light source device 400 in accordance with an embodiment of the invention. The light source 400 includes a red LED 402, a blue LED 404, and a green LED 406 formed on a solid-state structure 169. By including an array of red, green, and blue LEDs on a low cost substrate, such as glass, the light source 400 can provide a solid-state “white” light source suitable for many conventional applications, such as room and display lighting. The solid-state light source has significant advantages over conventional light sources, such as incandescent and fluorescent lighting, in that is more efficient and generates less heat.

The structure 169 that includes a glass or quartz substrate 163, a thermal oxide layer 165, and a monocrystalline silicon layer 161 is formed on the substrate 163 much as described above in connection with FIGS. 4-19. An amorphous intermediate layer 162 and an accommodating buffer layer 164, similar to those previously described, have been formed in regions over layer 161. Each region corresponds to an LED of the array. Layers 162 and 164 may be subject to an annealing process as described above in connection with FIG. 3 to form a single amorphous accommodating layer.

The wavelength, and thus the color of light emitted by an LED or laser diode, depends on the bandgap energy E_{g}. LEDs or laser diodes that emit light in the red-to-yellow spectrum have been available since the 1970's. The red LED 402 consists of a conventional AlGaAs surface-emitting LED having an n type GaAs layer 428 (first layer), a n-AlGaAs layer 430 (second layer), a p-GaAs layer 432 (third layer), a p-AlGaAs layer 434 (fourth layer), and a p-GaAs layer 436 (fifth layer), and conductors 408, 410 for providing current to the LED 402.

Extending LED light sources into the short-wavelength region of the spectrum, the region extending from green to violet, is desirable because LEDs can then be used to produce light in all three primary colors, i.e., red, green, and blue. Shorter-wavelength LEDs enable full-color displays.

FIG. 54 shows an exemplary LED structure 404, 406 for green and blue LEDs in which an InGaN active layer 422 (second layer) is formed over a group III-V nitride layer 420 (first layer). The group III-V nitride layer 420 is formed on the buffer layer 164. The group III-V nitride layer 420 is typically GaN. The InGaN active layer 422 is formed on the group III-V nitride layer 420. A second group III-V nitride layer 424 (third layer), such as AlGaN, is formed on the InGaN active layer 422. A third group III-V nitride layer 426 (fourth layer), such as an InGaN layer, is formed on the second group III-V layer 424. The first group III-V nitride layer 420 is n-type doped. The second and third group III-V nitride layers 424 and 426 are p-type doped. P-electrodes 412, 416 are formed on the third group III-V nitride layer 426. N-electrodes 414, 418 are formed on the first group III-V nitride layer 420. The compounds stated as being used in each of layers 420, 422, 424, 426 are formed in each layer using a predetermined molar fraction of the compound. These predetermined molar fractions, called herein a first set of molar fractions, are selected in a manner well known to one of ordinary skill in the art to achieve a desired color for LED 404. The compounds used for layers 440, 442, 444, 446 of LED 406 are, respectively, the same compounds used for layers 420, 422, 424, 426 of LED 404, but have different molar fractions. A second set of molar fractions is selected for the layers 440, 442, 444, 446 of LED 406 to achieve the desired color for LED 406.

Other suitable compound semiconductor materials, such as InP, can be used for the LEDs 402-406.

Although only three LEDs are illustrated in FIG. 54, the lighting source 400 can include an array of LEDs having a multitude of red, blue and green LEDs. The various colored LED can be placed on the structure 169 in a regular pattern or randomly arranged.

The LEDs 402-406 can be formed in any order. According to one embodiment, the different color arrays of LEDs 402-406 can be fabricated in the following fashion. Layers 162 and 164 are formed over essentially the entire substrate 161, and then the layers 428-436 for the LED 402 are formed over the layers 162, 164. A passivation layer of, for example, silicon dioxide or silicon nitride, is then deposited over the LED structure 402. After this step, the layers down to approximately the surface of layer 161 are etched away from the substrate, except for the material protected by the passivation layer (regions of the red LED 402). Next, layers 162, 164 are re-formed adjacent to the layers 162, 164 underlying the LED 402, which can cause the cavity 511. The layers 420-426 of the LED 404 are then formed, and a passivation layer is deposited over the LED 404. The layers are then etched away down to approximately the surface of layer 161, and then adjacently re-formed, which may result in the cavity 513. The layers 440-446 of the LED 406 are then formed. After the last LED 406 is formed, the passivation layers are removed from LED 402-404 by etching. Annealing may be performed after the layers 428-436, 420-426, and 440-446 for all the LEDs and the layers 162, 164 underlying all the LEDs have been formed.

The conductors 408-418 are then deposited. The conductors 408-418 can be connected to electronic driver circuitry composed of circuit components, such as those described in connection with FIGS. 40-46.

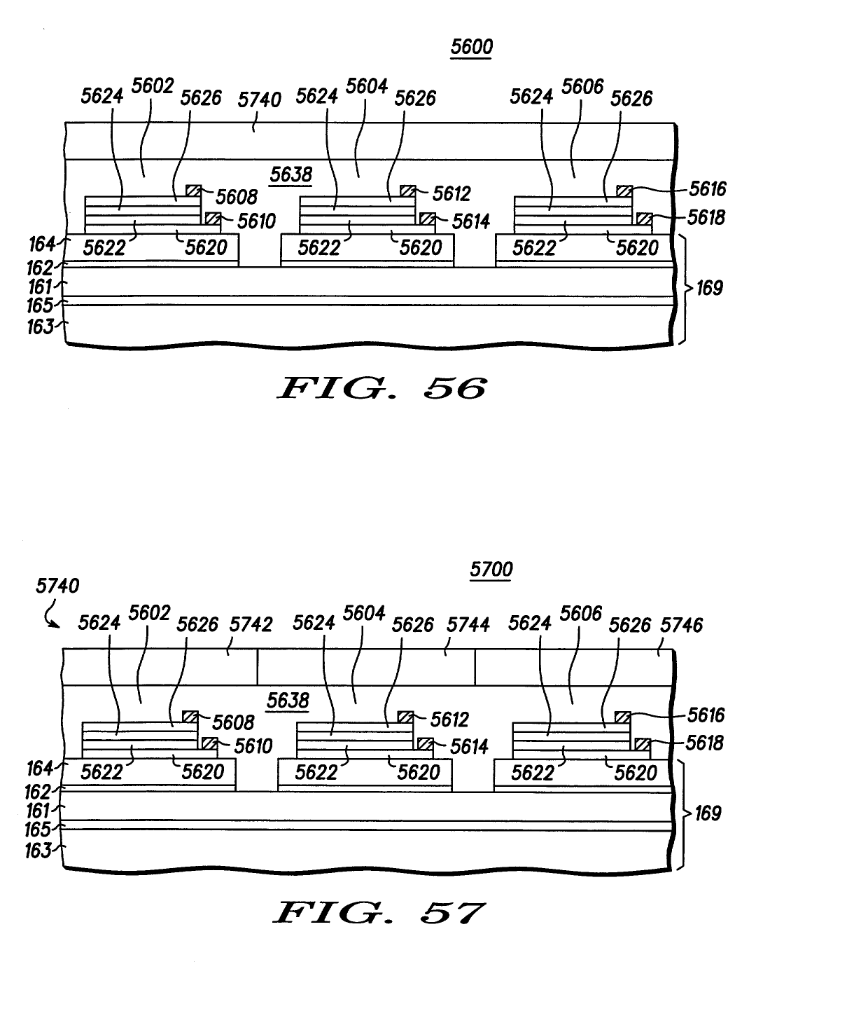

Referring now to FIG. 55, a flow chart shows a process for fabricating a semiconductor structure. The flow chart includes some of the steps used in the process. The details of how these steps are performed are described herein above. Other steps of the process are described herein above, or would be obvious to one of ordinary skill in the art. At step 5500, a glass substrate is provided, meaning it is prepared for use in equipment that can perform the next step of the process. At step 5505, a monocrystalline silicon layer is formed overlying the glass substrate. A monocrystalline perovskite oxide film is deposited overlying the substrate at step 5510, the film having a thickness less than a thickness of the material that would result in strain-induced defects. An amorphous oxide interface layer containing at least silicon and oxygen is formed at step 5515, at an interface between the monocrystalline perovskite oxide film and the substrate. A monocrystalline compound semiconductor layer is epitaxially formed, overlying the monocrystalline perovskite oxide film, at step 5520.

Referring now to FIG. 56, a cross sectional diagram illustrates a portion of a light source device 5600 in accordance with another embodiment of the invention. The light source 5600 includes an array of very short wavelength blue LEDs including LEDs 5602-6 formed on a solid-state structure 169. Each of the blue LEDs are coated with a layer of phosphor 5640, which absorbs the light energy from the blue LEDs 5602 and emits a substantial portion of the absorbed energy as white light, thereby “converting” the light energy from one light band to another. The phosphor is a transparent polymeric film that contains a flourescent compound dispersed therein. By including an array of blue LEDs 5602 coated with phosphor on a low cost substrate, such as glass, the light source 5600 can provide a solid-state “white” light source suitable for many conventional applications, such as room and display lighting. The solid-state light source 5600 has significant advantages over conventional light sources, such as incandescent and fluorescent lighting, in that it is more compact, more rugged, and in some cases more efficient.

The structure 169 includes a glass or quartz substrate 163, a thermal oxide layer 165, and a monocrystalline silicon layer 161 formed on the substrate 163 as described above in connection with FIGS. 4-19. An amorphous intermediate layer 162 and an accommodating buffer layer 164, similar to those previously described, have been formed over layer 161 in regions corresponding to the locations of the LEDs in the array. Layers 162 and 164 may be subject to an annealing process as described above in connection with FIG. 3 to form a single amorphous accommodating layer in each region.

Each blue LED comprises an InGaN active layer 5622 (second layer) is formed over a group III-V nitride layer 5620 (first layer). The group III-V nitride layer 5620 is formed on the buffer layer 164. The group III-V nitride layer 5620 is typically GaN. The InGaN active layer 5622 is formed on the group III-V nitride layer 5620. A second group III-V nitride layer 5624 (third layer), such as AlGaN, is formed on the InGaN active layer 5622. A third group III-V nitride layer 5626 (fourth layer), such as an InGaN layer, is formed on the second group III-V layer 5624. The first group III-V nitride layer 5620 is n-type doped. The second and third group m-v nitride layers 5624 and 5626 are p-type doped. P-electrodes 5608, 5612, 5616 are formed on the third group III-V nitride layer 5626. N-electrodes 5610, 5614, 5618 are formed on the first group III-V nitride layer 5620.

Other suitable compound semiconductor materials, such as InP, can be used for the LEDs 5602-5606.

The blue LEDs 5602 are preferably spaced on the structure 169 at intervals in a regular pattern arranged such that the light energy emitted (i.e., the brightness of the light emitted) by the phosphor material in response to the light energy received from the LEDs when the LEDs are all activated is essentially uniform. However, other useful patterns are just as feasible.

The LEDs 5602-5606 can be formed at the same time. According to one embodiment, the LEDs 5602-5606 can be fabricated in the following fashion. The layers 162 and 164 are formed, and then the layers 5620-5626 for the LED 402 are formed. A passivation layer of, for example, silicon dioxide or silicon nitride, is then deposited over the LEDs structure 5602-5606 leaving spaces between the LEDs. After this step, the layers in the spaces are etched away essentially down to the surface of layer 161, except for the material protected by the passivation layer forming the cavities 5611, 5613.

The conductors 5608-5618 are then deposited. The conductors 5608-5618 can be connected to electronic driver circuitry composed of circuit components, such as those described in connection with FIGS. 40-46. The conductors 5608, 5612, 5616 and 5610, 5614, 5618 can be coupled in common as two nodes to all the blue LEDs 5602-5606 so that the light source device is essentially entirely on or off. Alternatively, the conductors can be arranged to independently control LEDs beneath different areas of the light source device 5600, or the LEDs 5602-5606 can be arranged such that every Nth LED 5602-5606 can be turned off, allowing the light source 5600 to be dimmed. Such control can be achieved by connecting one set of conductors 5608, 5612, and 5616, or the other set of conductors 5610, 5614, and 5618 together and applying a common voltage (e.g., ground) thereto, and independently connecting the conductors of the set not commonly connected to a plurality of control voltages.

After the conductors 5608-5618 are formed, a transparent layer of insulating material 5638, such as silicon dioxide, silicon nitride, or spun on glass, is formed over the LEDs using conventional techniques, then the layer of phosphor 5640 is formed over the insulating material, using a conventional technique such as ink jet printing or screen printing. The insulating layer 5638 can be formed by depositing sufficient material to fill the cavities 5611, 5613, followed by a planarization operation to provide a flat surface for the formation of the phosphor layer 5640. The phosphor layer 5640 is a conventionally available fluorescent material in a polymeric matix that converts a relatively narrow band of ultraviolet light to a band of “white” light (i.e, light of the type marketed as white light for architectural or other artificial lighting purposes). It will be appreciated that another phosphor could be used to convert one band of light near one wavelength (of which blue is one example) to another band of light, for example yellow—to make a light for a traffic signal. The bands of light emitted by the LEDs and the phosphors may be of different bandwidths and have different center frequencies (colors).

Referring now to FIG. 57, a cross sectional diagram illustrates a portion of a light source device 5700 in accordance with yet another embodiment of the invention. The light source device 5700 is similar to light source device 5600, the significant difference being that the phosphor layer 5740 comprises regions: a blue region 5742, a red region 5744, and a green region 5746. The light source 5700 is formed in the same manner as light source 5600, except that when the layer of phosphor 5740 is formed, different phosphors are used in different regions 5742, 5744, 5746. Each of the phosphors can convert light energy in the band emitted by the LEDS 5602-5606 to different bands of light, such as red, blue, and green. In one variation of this embodiment, some regions are left without any phosphor, so that the light emitted from the LEDs in these regions is emitted through the transparent insulating material 5638. In this variation, visible band of light is emitted by the LEDs, so that the light source is capable of displaying at least two colors using at least one type of phosphor, including the band of light emitted by the LEDs and the band(s) of light emitted by the at least one type of phosphor. Maximum pixelation of the light source 5700 is accomplished by individually controlling a voltage applied at each of the pair of conductors connected to each LED. Such voltage control is typically accomplished by using one or both of the conductors at each LED as a control node. By having sufficiently small sized LEDs and phosphor regions, the light source 5700 can be operated as a full color display, for instance, a computer monitor. In this instance, the quantity of control nodes typically corresponds to the number of regions of phosphor.

In alternative embodiments to those described with reference to FIGS. 56 and 57, the transparent insulating layer 5638 is left out and the phosphor (FIG. 56) or phosphors (FIG. 57) are formed directly onto the LEDs and into the cavities therebetween. These embodiments can be used when the phosphor is sufficiently nonconductive to avoid degrading the performance of the LEDS or circuits driving them. It will be appreciated that the circuits that drive the LEDS are preferably located in active regions of the silicon substrate formed during the fabrication of the light source devices 5600, 5700.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A semiconductor structure comprising:
a glass substrate;
a monocrystalline silicon layer overlying the glass substrate;
an amorphous oxide material overlying the monocrystalline silicon layer;
a monocrystalline perovskite oxide material overlying the amorphous oxide material; and
a monocrystalline compound semiconductor material overlying the monocrystalline perovskite oxide material.

2. The semiconductor structure of claim 1, wherein the monocrystalline silicon layer is formed on the glass substrate using a lateral solidification technique.

3. The semiconductor structure of claim 1, further comprising:
a light-emitting semiconductor component formed using the monocrystalline compound semiconductor material.

4. The semiconductor structure of claim 3, further comprising:
a layer of phosphor material over the light-emitting semiconductor that can convert light energy of one band emitted by the light-emitting semiconductor to a different light band.

5. The semiconductor structure of claim 1, where in the light-emitting semiconductor component is selected from the group consisting of a light emitting diode and a laser.

6. The semiconductor structure of claim 1, wherein the light-emitting semiconductor component includes:
a lower mirror layer formed using a first plurality of compound semiconductor layers overlying the monocrystalline compound semiconductor material; and
an upper mirror layer formed using a second plurality of compound semiconductor layers overlying the first plurality of compound semiconductor layers for creating an active region for photon generation between the upper mirror layer and the lower mirror layer.

7. The semiconductor structure of claim 1, wherein the light-emitting semiconductor component includes a light emitting diode comprising:
a first compound semiconductor layer overlying the monocrystalline compound semiconductor material;
a second compound semiconductor layer overlying the first compound semiconductor layer;
a third compound semiconductor layer overlying the second compound semiconductor layer; and
a fourth compound semiconductor layer overlying the third compound semiconductor layer.

8. The semiconductor structure of claim 1, further comprising:
an oxide layer between the glass substrate and the monocrystalline silicon layer.

9. A solid-state structure, comprising:
a glass substrate;
a plurality of monocrystalline silicon regions overlying the glass substrate;
an amorphous oxide material overlying the monocrystalline silicon regions;
a monocrystalline perovskite oxide material overlying the amorphous oxide material;
a monocrystalline compound semiconductor material overlying the monocrystalline perovskite oxide material; and
a plurality of light-emitting semiconductor components, formed over the monocrystalline silicon regions, using the compound semiconductor material.

10. The solid-state structure of claim 9, wherein the monocrystalline silicon regions are formed over the glass substrate using a lateral solidification technique.

11. The solid-state structure of claim 9, wherein the plurality of light-emitting semiconductor components operate at a common light band, further comprising a layer of phosphor material over the light-emitting semiconductor that can convert light energy emitted at the common light band by the light-emitting semiconductor components to a different light band.

12. The solid-state structure of claim 9, wherein the plurality of light-emitting semiconductor components operate at a common light band, further comprising a layer of phosphor material over the light-emitting semiconductor components that can convert the common light band to a different light band.

13. The solid-state structure of claim 12, wherein the plurality of light-emitting semiconductor components are spaced at intervals selected to provide an essentially uniform brightness of light emitted from the phosphor material when all the light-emitting components are activated.

14. The solid-state structure of claim 9, wherein the plurality of light-emitting semiconductor components operate at a common light band, further comprising a plurality of regions of at least one type of phosphor material over the light-emitting semiconductor components that can convert energy emitted at the common light band by the light-emitting semiconductor components to at least one light band different than the common light band, the at least one light band corresponding to the type of phosphor material.

15. The solid-state structure of claim 14, further comprising a quantity of control nodes coupled to the plurality of light-emitting semiconductor components, the quantity of control nodes corresponding to the number of regions of phosphor.

16. The solid-state structure of claim 14, wherein the number of types of phosphor material is three, and the at least one light bands are bands corresponding to the colors red, blue, and green.

17. The solid-state structure of claim 9, wherein the plurality of light-emitting semiconductor components include a red light-emitting semiconductor component, a blue light-emitting semiconductor component, and a green light-emitting semiconductor component arranged to produce visible white light.

18. The solid-state structure of claim 9, wherein the plurality of monocrystalline silicon regions are formed at predetermined locations on the glass substrate.

19. The solid state structure of claim 9, wherein at least one of the plurality of light-emitting semiconductor components is selected from the group consisting of a light emitting diode and a laser.

20. The solid-state structure of claim 9, wherein at least one of the light-emitting semiconductor components includes:
a lower mirror layer formed using a first plurality of compound semiconductor layers overlying the monocrystalline compound semiconductor material; and
an upper mirror layer formed using a second plurality of compound semiconductor layers overlying the first plurality of compound semiconductor layers for creating an active region for photon generation between the upper mirror layer and the lower mirror layer.

21. The solid-state structure of claim 9, wherein at least one of the light-emitting semiconductor components includes:
a first compound semiconductor layer overlying the monocrystalline compound semiconductor material;
a second compound semiconductor layer overlying the first compound semiconductor layer;
a third compound semiconductor layer overlying the second compound semiconductor layer; and
a fourth compound semiconductor layer overlying the third compound semiconductor layer.

22. The semiconductor structure of claim 9, further comprising:
an oxide layer between the glass substrate and the plurality of monocrystalline silicon regions.

23. A process for fabricating a semiconductor structure comprising:
providing a glass substrate;
forming a monocrystalline silicon layer overlying the glass substrate;
depositing a monocrystalline perovskite oxide film overlying the monocrystalline silicon layer, the film having a thickness less than a thickness of the material that would result in strain-induced defects;
forming an amorphous oxide interface layer containing at least silicon and oxygen at an interface between the monocrystalline perovskite oxide film and the monocrystalline silicon layer; and
epitaxially forming a monocrystalline compound semiconductor layer overlying the monocrystalline perovskite oxide film.

24. The process of claim 23, wherein the step of forming the monocrystalline silicon layer includes applying a lateral solidification technique.

25. The process of claim 23, wherein the step of forming the monocrystalline silicon layer includes:
depositing a silicon film over the glass substrate;
irradiating a first portion of the silicon film so as to melt the silicon film in the first portion;
permitting the melted silicon film in the first portion to solidify to form at least one silicon crystal;
irradiating a second portion of the silicon film that at least partially overlaps the at least one silicon crystal so as to melt the silicon film in the second portion; and
permitting the melted silicon film in the second portion to solidify to enlarge the at least one silicon crystal.

26. The process of claim 23, further comprising:
forming a light-emitting semiconductor component using the monocrystalline compound semiconductor material.

27. The process of claim 26, further comprising:
forming a layer of phosphor material over the light-emitting semiconductor that can convert energy emitted at one light band by the light-emitting semiconductor to a different light band.

28. The process of claim 23, wherein the step of forming the light-emitting semiconductor component includes:
forming a lower mirror layer over the monocrystalline compound semiconductor material; and
forming an upper mirror layer over the lower mirror layer for creating an active region for photon generation between the upper mirror layer and the lower mirror layer.

29. The process of claim 23, wherein the step of forming the light-emitting semiconductor component includes:
forming a first compound semiconductor layer overlying the monocrystalline compound semiconductor material;
forming a second compound semiconductor layer overlying the first compound semiconductor layer;
forming a third compound semiconductor layer overlying the second compound semiconductor layer; and
forming a fourth compound semiconductor layer overlying the third compound semiconductor layer.

30. The process of claim 23, further comprising:
forming an oxide layer between the glass substrate and the monocrystalline silicon layer.

31. A process for fabricating a semiconductor structure comprising:
providing a glass substrate;
forming a plurality of monocrystalline silicon regions over the glass substrate;
depositing a monocrystalline perovskite oxide film overlying the plurality of monocrystalline silicon regions, the film having a thickness less than a thickness of the material that would result in strain-induced defects;
forming an amorphous oxide interface layer containing at least silicon and oxygen at an interface between the monocrystalline perovskite oxide film and the plurality of monocrystalline silicon regions; and
epitaxially forming a monocrystalline compound semiconductor layer overlying the monocrystalline perovskite oxide film.

32. The process of claim 31, further comprising:
forming a plurality of light-emitting semiconductor components, over the plurality of monocrystalline silicon regions, using the monocrystalline compound semiconductor material.

33. The process of claim 31, wherein the plurality of light-emitting semiconductor components are formed to operate at a common wavelength, further comprising forming a layer of phosphor material over the light-emitting semiconductor that can convert energy emitted at one light band by the light-emitting semiconductor components to a different light band.

34. The process of claim 31, wherein the plurality of light-emitting semiconductor components are formed to operate at a common light band, further comprising forming a layer of phosphor material over the light-emitting semiconductor components that can convert energy emitted at the common light band by the light-emitting semiconductor components to a light band different than the common light band.

35. The process of claim 34, wherein during the forming, the plurality of light-emitting semiconductor components are spaced at intervals arranged to provide an essentially uniform brightness of light emitted from the phosphor material when all the light-emitting components are activated.

36. The process of claim 31, wherein the plurality of light-emitting semiconductor components are formed to operate at a common light band, further comprising forming a plurality of regions of at least one type of phosphor material over the light-emitting semiconductor components that can convert energy emitted at the common light band by the light-emitting semiconductor components to at least one light band different than the common light band, the at least one light band corresponding to the type of phosphor material.

37. The process of claim 36, further comprising forming a plurality of control nodes corresponding to the number regions of phosphor.

38. The process of claim 36, wherein the number of types of phosphor material is three, and the at least one light bands are wavelengths corresponding to the colors red, blue, and green.

39. The process of claim 31, wherein the step of forming the plurality of light-emitting semiconductor components includes:
forming a first light-emitting semiconductor component operating at a first wavelength; and
forming a second light-emitting semiconductor component operating at a second wavelength different from the first wavelength.

40. The process of claim 31, wherein the step of forming the plurality of light-emitting semiconductor components includes:
forming a red light-emitting semiconductor component, a blue light-emitting semiconductor component, and a green light-emitting semiconductor component arranged in a predetermined pattern for producing visible white light.

41. The process of claim 31, wherein the step of forming the plurality of light-emitting semiconductor components includes:
forming a lower mirror layer overlying the monocrystalline compound semiconductor material; and
forming an upper mirror layer overlying the lower mirror layer for creating an active region for photon generation between the upper mirror layer and the lower mirror layer.

45. The process of claim 31, further comprising:
forming an oxide layer between the glass substrate and the plurality of monocrystalline silicon regions.
